(19) United States
(12) Patent Application Publication
(10) Pub. No.: US 2026/0221960 A1
(43) Pub. Date: Jul. 30, 2026

(54) METHODS AND APPARATUS FOR PHASE INTERPOLATION

(71) Applicant: Texas Instruments Incorporated, Dallas, TX (US)

(72) Inventors: Cheng Li, Sunnyvale, CA (US); Ramsin Ziazadeh, San Jose, CA (US); Hung Jung Chen, Cupertino, CA (US); Anindita Borah, Santa Clara, CA (US)

(21) Appl. No.: 19/041,460

(22) Filed: Jan. 30, 2025

(51) Int. Cl. H03K 5/135; G06F 3/14; G08G 9/00; H03K 5/00; H03L 7/08

(52) U.S. Cl. CPC H03K 5/135; G06F 3/14; G08G 9/00; H03K 2005/00052; H03L 7/0807

(57) ABSTRACT

An example apparatus includes: first voltage-to-current (V-I) circuitry having a first terminal and a second terminal; second V-I circuitry having a first terminal and a second terminal; a first transistor having a first terminal, a second terminal, and a control terminal, the first terminal of the first transistor coupled to the first terminal of the first V-I circuitry and the first terminal of the second V-I circuitry; a second transistor having a first terminal, a second terminal, and a control terminal, the first terminal of the second transistor coupled to the second terminal of the first V-I circuitry and the second terminal of the second V-I circuitry; a first resistor having a first terminal and a second terminal, the first terminal of the first resistor coupled to the second terminal of the first transistor, the second terminal of the first resistor coupled to the control terminal of the second transistor.

### TECHNICAL FIELD

This description relates generally to producing clock signals for a system and, more particularly, to methods and apparatus for phase interpolation to produce clock signals.

### BACKGROUND

Electrical components form a system by performing a series of operations. In some systems, electrical components sequence the performance of operations using a clock signal. In serializer systems, a clock signal sequences the formation of a serial data stream from a plurality of parallel data streams. In deserializer systems, a clock signal sequences the formation of a plurality of parallel data streams from a serial data stream. Such systems include phase interpolator (PI) circuitry to produce the clock signal having a phase. The PI circuitry controls the phase of the clock signal responsive to a control value.

### SUMMARY

For methods and apparatus for phase interpolation, an example apparatus includes first voltage-to-current (V-I) circuitry having a first terminal and a second terminal; second V-I circuitry having a first terminal and a second terminal; a first transistor having a first terminal, a second terminal, and a control terminal, the first terminal of the first transistor coupled to the first terminal of the first V-I circuitry and the first terminal of the second V-I circuitry; a second transistor having a first terminal, a second terminal, and a control terminal, the first terminal of the second transistor coupled to the second terminal of the first V-I circuitry and the second terminal of the second V-I circuitry; a first resistor having a first terminal and a second terminal, the first terminal of the first resistor coupled to the second terminal of the first transistor, the second terminal of the first resistor coupled to the control terminal of the second transistor; and a second resistor having a first terminal and a second terminal, the first terminal of the second resistor coupled to the second terminal of the second transistor, the second terminal of the second resistor coupled to the control terminal of the first transistor. Other examples are described.

For methods and apparatus for phase interpolation, an example apparatus includes clock circuitry having a first output and a second output; phase interpolator circuitry including: first voltage-to-current (V-I) circuitry having a first input, a second input, a first output, and a second output; second V-I circuitry having a first input, a second input, a first output, and a second output, the first input of the second V-I circuitry coupled to the first output of the clock circuitry and the second input of the first V-I circuitry, the second input of the second V-I circuitry coupled to the second output of the clock circuitry and the first input of the first V-I circuitry; and filter circuitry having a first input, a second input, and an output, the first input of the filter circuitry coupled to the first output of the first V-I circuitry and the first output of the second V-I circuitry, the second input of the filter circuitry coupled to the second output of the first V-I circuitry and the second output of the second V-I circuitry; and current mode logic (CML) to complementary metal oxide semiconductor (CMOS) converter circuitry having an input coupled to the output of the filter circuitry. Other examples are described.

For methods and apparatus for phase interpolation, an example apparatus includes first voltage-to-current (V-I) circuitry having a first output and a second output; second V-I circuitry having a first output and a second output; and filter circuitry having a first input and a second input, the first input of the filter circuitry coupled to the first output of the first V-I circuitry and the first output of the second V-I circuitry, the second input of the filter circuitry coupled to the second output of the first V-I circuitry and the second output of the second V-I circuitry, the filter circuitry configured to: combine first currents at the first output of the first V-I circuitry and the first output of the second V-I circuitry; combine second currents at the second output of the first V-I circuitry and the second output of the second V-I circuitry; filter the combined first currents and the combined second currents; and generate a current mode logic (CML) clock signal based on the filtering. Other examples are described.

### BRIEF DESCRIPTION OF THE DRAWINGS

FIG. 1 is a block diagram of an example vehicle including an example advanced driver-assistance (ADAS) system and an example in-vehicle infotainment (IVI) system, that may use phase interpolator circuitry in described examples.

FIG. 2 is a block diagram of an example of the ADAS system of FIG. 1 including example deserializer circuitry and example serializer circuitry, that may use phase interpolator circuitry in described examples.

FIG. 3 is a block diagram of an example IVI system of FIG. 1 including example serializer circuitry, and example deserializer circuitry, that may use phase interpolator circuitry according in examples.

FIG. 4 is a block diagram including examples of the serializer and deserializer circuitry of FIGS. 2 and 3, which may be referred to as a serial-deserializer (SerDes) system, the serializer and deserializer circuitry further including retimer circuitry, that may use phase interpolator circuitry in described examples.

FIG. 5 is a block diagram of an example of the retimer circuitry of FIG. 4 including example phase interpolator circuitry.

FIG. 6 is a flowchart representative of example machine-readable instructions or example operations that may be at least one of executed, instantiated, or performed using an example implementation of the retimer circuitry of FIG. 5.

FIG. 7 is a block diagram of an example of the phase interpolator circuitry of FIG. 5.

FIG. 8 is a schematic diagram of an example of the phase interpolator circuitry of FIGS. 5 and 7 including example multi-order filter circuitry and voltage-to-current (V-I) circuitry.

FIG. 9 is a timing diagram of example clock signals having different phases for phase interpolation.

FIG. 10 is a timing diagram of example phase interpolator operations of the retimer circuitry of FIG. 5.

FIG. 11 is a flowchart representative of example machine-readable instructions or example operations that may be at least one of executed, instantiated, or performed using an example implementation of the phase interpolation circuitry of FIGS. 5, 7, and 8.

FIG. 12 is a plot of example filter operations of the phase interpolator circuitry of FIGS. 5, 7, and 8.

FIG. 13 is a schematic diagram of an example of the phase interpolator circuitry of FIGS. 5, 7, and 8 for oscillator multiplexing.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

Electrical components form a system by performing a series of operations. In some systems, electrical components sequence the performance of operations using a clock signal. In serializer systems, a clock signal sequences the formation of a serial data stream from a plurality of parallel data streams. In deserializer systems, a clock signal sequences the formation of a plurality of parallel data streams from a serial data stream. Such systems include phase interpolator (PI) circuitry to produce the clock signal having a phase. The PI circuitry controls the phase of the clock signal responsive to a control value.

Some PI circuitry includes a plurality of voltage to current (V-I) circuitry. The plurality of V-I circuitry produces a PI clock signal responsive to mixing currents based on an in-phase (I) signal, a quadrature (Q) signal, and a control value. The in-phase and quadrature signals are clock signals (e.g., pulse width modulation (PWM) signals) that are ninety degrees out of phase from each other. In some examples, the PI circuitry also receives an inverted in-phase clock signal and an inverted quadrature clock signal. The control value sets the magnitudes of currents from the V-I circuity, which forms the PI clock signal. The in-phase and quadrature clock signals control the sinking of current by the V-I circuitry from one of two nodes (e.g., terminals). At the first node, the combination of currents produces the PI clock signal. At the second node, the combination of currents produces an inverted PI clock signal, which is one-hundred and eighty degrees out of phase from the PI clock signal.

In operation, the phase of the PI clock signal is set by the magnitude of currents being sunk by the V-I circuitry. For example, the control value sets the phase of the PI clock signal less than ninety degrees responsive to mixing higher currents from the in-phase and inverted in-phase clock signals and smaller currents from the quadrature and inverted quadrature clock signals. In such operations, the PI circuitry is linear if each increment of the control value corresponds to the same change in phase. However, the V-I circuitry may suffer poor linearity as the phase of the PI clock signal transitions between the phases represented by the in-phase signal and the phases represented by the quadrature signal. Also, parasitic inductance and capacitance of the plurality of V-I circuitry may degrade power efficiency and bandwidth responsive to compounding at the first and second nodes.

Examples described herein include methods and apparatus for improved phase interpolation. In some examples, PI circuitry includes a plurality of V-I circuitry, load circuitry, and filter circuitry. The plurality of V-I circuitry produces a plurality of currents responsive to an in-phase signal, a quadrature signal, an inverted in-phase signal, an inverted quadrature signal, and a control value. Each of the plurality of V-I circuitry sink currents of a magnitude corresponding to a portion of the control value. For example, if the PI circuitry includes four instances of the V-I circuitry, the control value is divided into four portions that individually control each of the plurality of V-I circuitry. In such an example, the in-phase and inverted in-phase signals control the first and second V-I circuitry and the quadrature and inverted quadrature signals control the third and fourth V-I circuitry. The plurality of V-I circuitry sink currents from one of a first or second input of the filter circuitry.

In such example operations, the load circuitry supplies current to the filter circuitry responsive to the currents of the plurality of V-I circuitry. Also, the load circuitry includes components to impedance match the filter circuitry. The filter circuitry produces virtual common potentials (also referred to as virtual grounds) at the first and second inputs of the filter circuitry responsive to the impedance matching of the load circuitry. Advantageously, isolating the generation of the PI clock signal from the V-I circuitry using the virtual common potentials improves the linearity of the PI circuitry. The filter circuitry performs a multi-order filtering of the currents of the V-I circuitry to produce a current mode logic (CML) PI clock signal. Such multi-order filtering reduces inter-symbol interference (ISI) and jitter by filtering harmonics. Advantageously, filtering multi-order harmonics improves the performance of the PI circuitry across a larger bandwidth, specifically at higher frequencies. Also, the filter circuitry amplifies the currents of the V-I circuitry responsive to including additional impedances between the load circuitry and the output of the PI circuitry. Advantageously, the additional impedances of the filter circuitry allow the PI circuitry to support higher voltage swings of the PI clock signal.

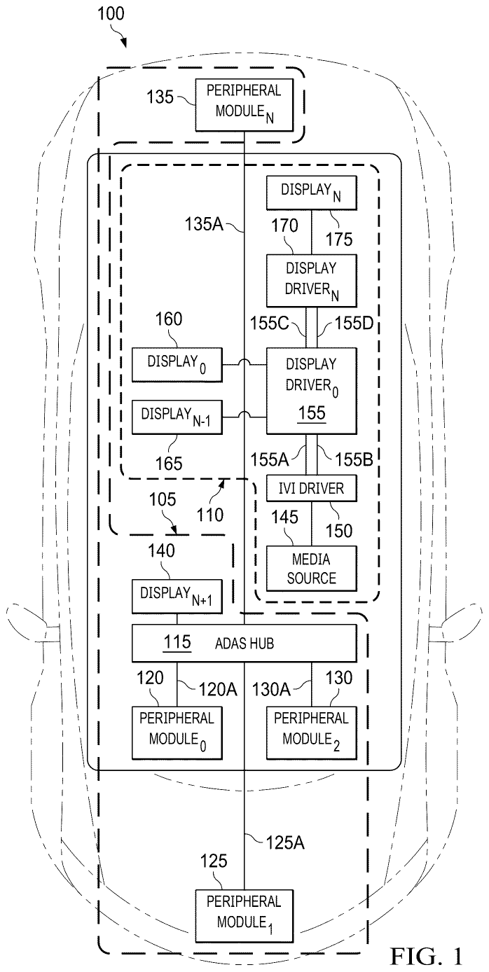

FIG. 1 is a block diagram of an example vehicle 100 including an example advanced driver-assistance (ADAS) system 105 and an example in-vehicle infotainment (IVI) system 110. The ADAS system 105 and the IVI system 110 may utilize a suitable interface technology to transfer serial data between various components of the system, for instance to display media, such as images, multi-media content, etc. In one example, the ADAS system 105 and the IVI system 110 utilize flat panel display (FPD)-link interface technology to transfer the serial data and are, thereby, referred to as FPD-link systems. In some examples, the vehicle 100 may include one or more instances of the ADAS system 105 or the IVI system 110. For example, the vehicle 100 may include one or more instances of the ADAS system 105 without the IVI system 110. In another example, the vehicle 100 may include one or more instances of the IVI system 110 without the ADAS system 105. In yet another example, the vehicle 100 may include one or more instances of the ADAS system 105 and one or more instances of the IVI system 110. In the example of FIG. 1, the vehicle 100 is illustrated as a system for traversing distances, such as a car, a truck, etc. Alternatively, the vehicle 100 may be replaced, illustrated, or described as an alternative distributed display system, such as a boat, airplane, spacecraft, workstation, control panel, etc.

The ADAS system 105 of FIG. 1 includes an example ADAS hub 115, a first example peripheral module 120, a second example peripheral module 125, a third example peripheral module 130, a fourth example peripheral module 135, and an example display 140. Alternatively, the ADAS system 105 may include any number of peripheral module(s) or display(s).

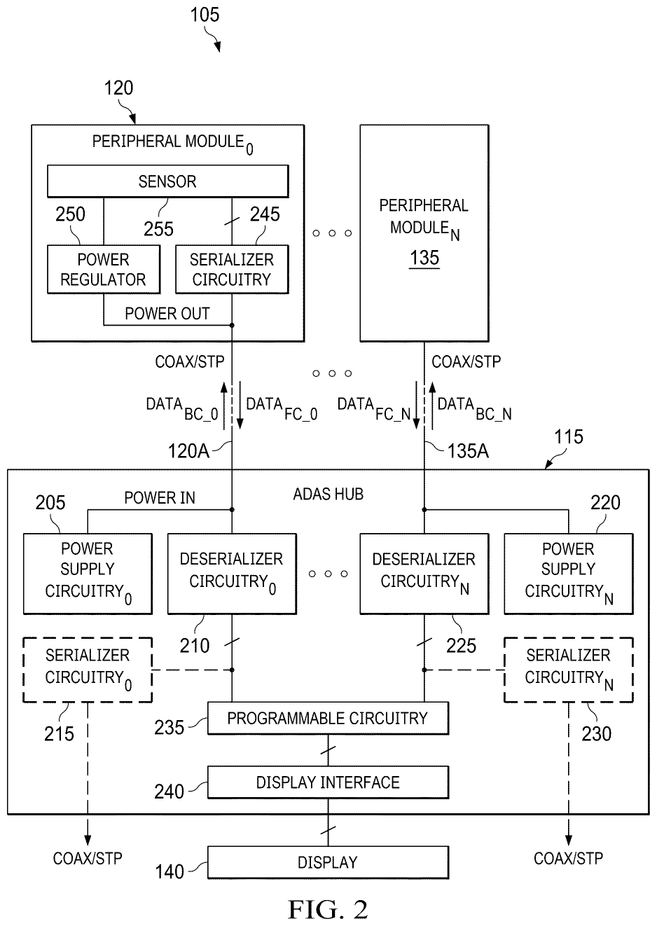

The ADAS system 105 is an example type of system that utilizes serializing and deserializing data for driving assistance in the vehicle 100. In an example, the ADAS system 105 is an FPD-link system. In some examples, the ADAS system 105 utilizes serializing and deserializing media for an alternative implementation of processing, storing, or displaying data, such as a security system, recording system, etc. In some examples, the ADAS system 105 is an example camera system that facilitates at least one of the storing, processing, or displaying multi-media data (e.g., images, videos, etc.) from one or more sensors, such as cameras. In other examples, the ADAS system 105 may facilitate at least one of the storing, processing, or displaying an alternative type of data from one or more alternative types of sensors (e.g., lidar, radar, ultrasonic, etc.). An example of the ADAS system 105 is further illustrated and described in connection with FIG. 2.

The ADAS hub 115 is communicatively coupled to the peripheral modules 120, 125, 130, 135 and the display 140. The ADAS hub 115, as part of an FPD-link system for example, uses full-duplex communications to transmit data to and receive data from the peripheral modules 120, 125, 130, 135. However, other systems may use a different type of technology to transfer the serial data, for example using half duplex communications, e.g., using a time-division duplexing (TDD). In some examples, the ADAS hub 115 uses low-voltage differential signaling (LVDS) to communicate with the peripheral modules 120, 125, 130, 135. Alternatively, the ADAS hub 115 may use an alternative type of signaling to communicate with the peripheral modules 120, 125, 130, 135, such as display serial interface (DSI), embedded display port (eDP), etc. The ADAS hub 115 may at least one of store, process, or display data from the peripheral modules 120, 125, 130, 135. In the example of FIG. 1, the ADAS hub 115 displays the data from one or more of the peripheral modules 120, 125, 130, 135 using the display 140. The ADAS hub 115 uses multi-lane signaling to display data using the display 140. Also, the ADAS hub 115 may also at least one of store or process data from the peripheral modules 120, 125, 130, 135 for other functions of the vehicle 100, such as object recognition, time of flight calculations, etc. An example of the ADAS hub 115 is further illustrated and described in connection with FIG. 2.

The peripheral modules 120, 125, 130, 135 are communicatively coupled to the ADAS hub 115. The peripheral modules 120, 125, 130, 135 include at least one sensor that receives information of the surrounding environment, such as images, videos, time of flight measurements, beamforming data, etc. The peripheral modules 120, 125, 130, 135 transmit the obtained sensor data to the ADAS hub 115 using communication channels 120A, 125A, 130A, 135A. In some examples, the communication channels 120A, 125A, 130A, 135A are coaxial connectors, which couple the ADAS hub 115 to the peripheral modules 120, 125, 130, 135. In such examples, the ADAS hub 115 supplies power to the peripheral modules 120, 125, 130, 135 using power over coax (POC) across the communication channels 120A, 125A, 130A, 135A. Alternatively, the communication channels 120A, 125A, 130A, 135A may be formed by a different type of connector, such as a standard twisted pair (STP). An example of the peripheral modules 120, 125, 130, 135 are further illustrated and described in connection with FIG. 2.

In example operation of the ADAS system 105 of FIG. 1, the peripheral modules 120, 125, 130, 135 produce video streams of the environment surrounding the vehicle 100. The peripheral modules 120, 125, 130, 135 serialize data of the video streams. The peripheral modules 120, 125, 130, 135 transmit the serial data streams to ADAS hub 115 using the communication channels 120A, 125A, 130A, 135A. Concurrently, the ADAS hub 115 may transmit data to the peripheral modules 120, 125, 130, 135 using the communication channels 120A, 125A, 130A, 135A.

Communications between the ADAS hub 115 and the peripheral modules 120, 125, 130, 135 may occur simultaneously. Such simultaneous multi-directional communications across the same one of the communication channels 120A, 125A, 130A, 135A are referred to as full-duplex communications. Full-duplex communications include simultaneous exchange of first communications across a front channel (also referred to as a forward channel) and second communications across a back channel. In example operations, the communications of the front channel traverse a direction opposite to communications of the back channel. Example communications of the front and back channel are further illustrated and described below. Alternatively, in some examples, communications may occur in a single direction during a given time frame, such as across the front channel or across the back channel. Such communications are referred to as half duplex communications

In such example operations of the ADAS system 105 of FIG. 1, the ADAS hub 115 receives the serial data streams from the peripheral modules 120, 125, 130, 135. The ADAS hub 115 deserializes the data streams to reconstruct the video streams captured by the peripheral modules 120, 125, 130, 135. The ADAS hub 115 at least one of stores, processes, or displays the video streams for driver assistance. For example, the ADAS hub 115 displays the video stream of the peripheral module 135 on the display 140 responsive to a determination that the perspective corresponding to the peripheral module 135 is needed. In another example, the ADAS hub 115 stores or process video streams of the peripheral modules 120, 125, 130, 135 for detecting safety hazards in the environment of the vehicle 100.

Example operations of the ADAS system 105 are further described in connection with FIG. 2. Advantageously, serializing and deserializing data from the peripheral modules 120, 125, 130, 135 reduces the number of connections within the vehicle 100 to the ADAS hub 115. Advantageously, the serial data streams can accurately traverse relatively large distances across the communication channels 120A, 125A, 130A, 135A.

The IVI system 110 of FIG. 1 includes an example media source 145, example IVI driver circuitry 150, a first example display driver 155, a first example display 160, a second example display 165, a second example display driver 170, and a third example display 175. Alternatively, the IVI system 110 may include any number of display driver(s) or display(s).

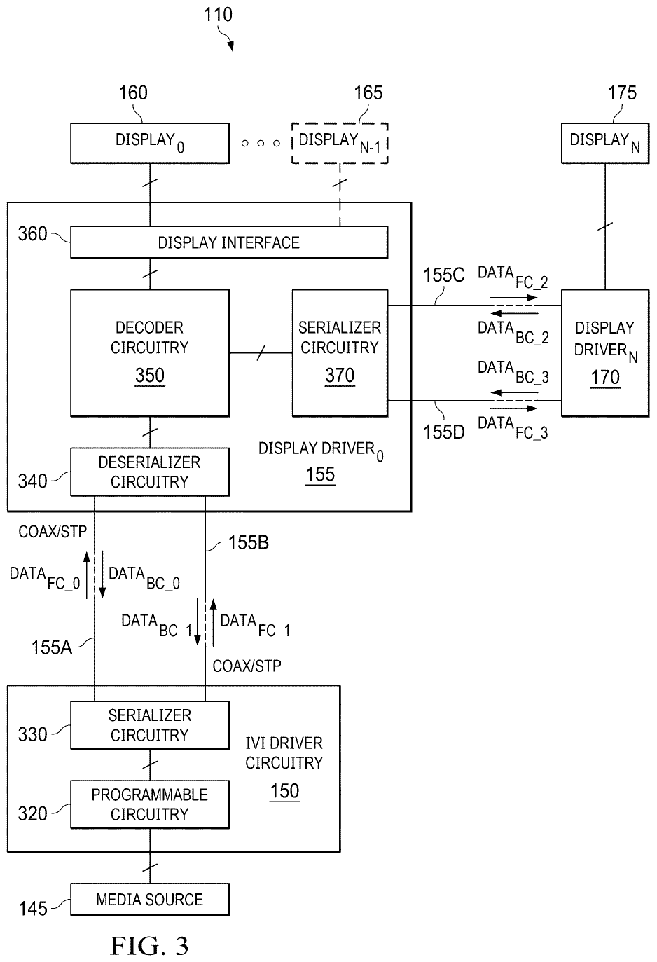

The IVI system 110 is an example type of that utilizes serializing and deserializing media for infotainment on one or more displays (e.g., the displays 160, 165, 175). In an example, the IVI system 110 is an FPD-link system. In some examples, the IVI system 110 is a dashboard having multiple displays for displaying content. In other examples, the IVI system 110 is a different display system having multiple displays for displaying content, such as a studio, workstation, etc. In the example of FIG. 1, the IVI system 110 includes the media source 145, the IVI driver circuitry 150, the display drivers 155, 170, and the displays 160, 165, 175. Alternatively, the IVI system 110 may include any number of media source(s), display driver(s), or display(s). An example of the IVI system 110 is further illustrated and described in connection with FIG. 3.

In the IVI system 110, the media source 145 is coupled to the IVI driver circuitry 150. The media source 145 supplies media to the IVI driver circuitry 150 for display on one or more of the displays 160, 165, 175. In some examples, the media source 145 is integrated in the vehicle 100, such as circuitry supporting a data stream or memory storing media. In other examples, the media source 145 represents a connection to a device that is external to the vehicle 100, such as a wireless connection to a service hosting a multi-media stream.

The IVI driver circuitry 150 is communicatively coupled to the media source 145 and the display driver 155. The IVI driver circuitry 150 processes multi-media data from the media source 145 for transmission to one or more of the display drivers 155, 170. The IVI driver circuitry 150 uses full-duplex communications to transmit data to and receive data from the display driver 155. In some examples, the IVI driver circuitry 150 uses LVDS to communicate with the display driver 155. In such examples, the IVI driver circuitry 150 indirectly communicates with the display driver 170 through the display driver 155. Such an example is further illustrated and described in connection with FIG. 3. Alternatively, the IVI driver circuitry 150 may use an alternative type of signaling to communicate with the display driver 155, such as DSI, eDP, etc. An example of the IVI driver circuitry 150 is further illustrated and described in connection with FIG. 3.

The display driver 155 is communicatively coupled to the IVI driver circuitry 150, the displays 160, 165, and the display driver 170. The display driver 155 interfaces with the IVI driver circuitry 150 using first and second communication channels 155A, 155B. The display driver 155 interfaces with the display driver 170 using third and fourth communication channels 155C, 155D. In the example of FIG. 1, first and second coaxial connectors form the communication channels 155A, 155B between the IVI driver circuitry 150 and the display driver 155. Similarly, third and fourth coaxial connectors form the communication channels 155C, 155D between the display drivers 155, 170. The display driver 155 uses multi-lane signaling to display media on the displays 160, 165. In some examples, the display driver 155 decodes additional data from the IVI driver circuitry 150 to determine which one of the displays 160, 165 corresponds to the data. Although the display driver 155 of FIG. 1 is coupled to the displays 160, 165, the display driver 155 may be coupled to any number of display(s). An example of the display driver 155 is further illustrated and described in connection with FIG. 3.

The display driver 170 is communicatively coupled to the display driver 155 and the display 175. In some examples, the display driver 170 may be coupled to another instance of the display driver 170 (similar to the communication channels 155A, 155B, 155C, 155D of the display driver 155). The display driver 170 interfaces with the display driver 155 using the communication channels 155C, 155D. The display driver 170 uses multi-lane signaling to display multi-media data using the display 175. Although the display driver 155 of FIG. 1 is coupled to the display 175, the display driver 170 may be coupled to any number of display(s).

In an example operation of the IVI system 110 of FIG. 1, the media source 145 supplies media for display on at least one of the displays 160, 165, 175. The IVI driver circuitry 150 determines one or more of the displays 160, 165, 175 to display the media from the media source 145. The IVI driver circuitry 150 determines which of the display drivers 155, 170 are coupled to the one or more of the displays 160, 165, 175. The IVI driver circuitry 150 generates an identifier(s) that specifies at least one of the one or more of the display drivers 155, 170 or one or more of the displays 160, 165, 175. The IVI driver circuitry 150 combines the identifying data and the media from the media source 145. The IVI driver circuitry 150 generates a serial data stream by serializing the combined data for transmission on at least one of the communication channels 155A, 155B.

In such example operations of the IVI system 110, the display driver 155 receives the serial data stream representing the media and identifying data. The display driver 155 deserializes the serial data stream(s) from the communication channels 155A, 155B. The display driver 155 decodes the identifying data to determine if the media corresponds to either of the displays 160, 165. If the display driver 155 determines that the media corresponds to one or more of the displays 160, 165, the display driver 155 displays the media on one or more of the displays 160, 165. If the display driver 155 determines that the media does not correspond to one or more of the displays 160, 165, the display driver 155 regenerates the serial data stream by reserializing the combined media and identifying data. The display driver 155 transmits the serial data to the display driver 170 via at least one of the communication channels 155C, 155D. After receiving the serial data stream from the communication channels 155C, 155D, the display driver 155 deserializes the serial data stream(s). The display driver 170 decodes the identifying data to determine if the media corresponds to the display 175. If the display driver 170 determines that the identifying data corresponds to the display 175, the display driver 170 displays the media on the display 175. In some examples, the display drivers 155, 170 transmit serial data along the communication channels 155A, 155B, 155C, 155D to the IVI driver circuitry 150. In such examples, the concurrent communications from the display drivers 155, 170 may confirm reception or display of the media on one or more of the displays 160, 165, 175.

Example operations of the IVI system 110 are further described in connection with FIG. 3. Serializing and deserializing media from the media source 145 reduces the number of connections to the displays 160, 165, 175 within the vehicle 100. Also, the serial data streams can accurately traverse relatively large distances across the communication channels 155A, 155B, 155C, 155D.

FIG. 2 is a block diagram of an example of the ADAS system 105 of FIG. 1 including the ADAS hub 115, the peripheral modules 120, 135, and the display 140 of FIG. 1. The example ADAS hub 115 of FIG. 2 includes first example power supply circuitry 205, first example deserializer circuitry 210, first example serializer circuitry 215, second example power supply circuitry 220, second example deserializer circuitry 225, second example serializer circuitry 230, example programmable circuitry 235, and example display interface circuitry 240. The example peripheral module 120 of FIG. 2 includes example serializer circuitry 245, example power regulator circuitry 250, and an example sensor 255.

The power supply circuitry 205 has an output coupled to the communication channel 120A and the deserializer circuitry 210. In some examples, the power supply circuitry 205 has an input coupled to a power storage or an electronic control unit (ECU), which supplies power. In other examples, the power supply circuitry 205 is in the peripheral module 120. In such examples, the power supply circuitry 205 directly supplies power to the peripheral module 120. Alternatively, a different method of powering the peripheral module 120 may be used with the circuitry described herein.

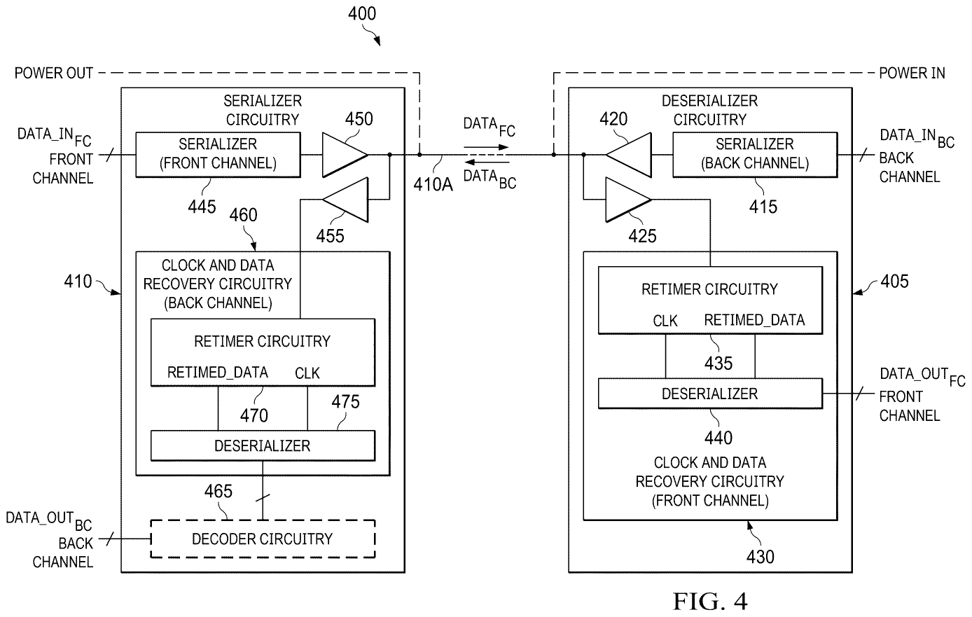

The deserializer circuitry 210 has an input and outputs. The input of the deserializer circuitry 210 is coupled to the communication channel 120A and the power supply circuitry 205. The outputs of the deserializer circuitry 210 are coupled to the serializer circuitry 215 and the programmable circuitry 235. In some examples, the deserializer circuitry 210 communicates with the peripheral module 120 using serial data streams along the communication channel 120A. An example of the deserializer circuitry 210 is further illustrated and described in connection with FIG. 4.

The serializer circuitry 215 has inputs and an output. The inputs of the serializer circuitry 215 are coupled to the deserializer circuitry 210 and the programmable circuitry 235. The output of the serializer circuitry 215 is structured to be coupled to an additional communication channel. In some examples, as illustrated by the dashed lines, the ADAS hub 115 may include the serializer circuitry 215 to connect the ADAS system 105 to external circuitry. In such examples, the serializer circuitry 215 may communicatively couple the ADAS system 105 to another ADAS system, the IVI system 110, storage medium, an ECU, etc. In other examples, the serializer circuitry 215 may be excluded from the ADAS hub 115.

The power supply circuitry 220 has an output coupled to the communication channel 135A and the deserializer circuitry 225. In some examples, the power supply circuitry 220 has an input coupled to a power storage or an ECU, which supplies power. In other examples, the power supply circuitry 220 is in the peripheral module 135. In such examples, the power supply circuitry 220 directly supplies power to the peripheral module 135. Alternatively, a different method of powering the peripheral module 135 may be used with the circuitry described herein.

The deserializer circuitry 225 has an input and outputs. The input of the deserializer circuitry 225 is coupled to the communication channel 135A and the power supply circuitry 220. The outputs of the deserializer circuitry 225 are coupled to the serializer circuitry 230 and the programmable circuitry 235. In some examples, the deserializer circuitry 225 communicates with the peripheral module 135 using serial data streams along the communication channel 135A. An example of the deserializer circuitry 225 is further illustrated and described in connection with FIG. 4.

The serializer circuitry 230 has inputs and an output. The inputs of the serializer circuitry 230 are coupled to the deserializer circuitry 225 and the programmable circuitry 235. The output of the serializer circuitry 230 is structured to be coupled to an additional communication channel. In some examples, as illustrated by the dashed lines, the ADAS hub 115 may include the serializer circuitry 230 to connect the ADAS system 105 to external circuitry. In such examples, the serializer circuitry 230 may communicatively couple the ADAS system 105 to another ADAS system, the IVI system 110, storage medium, an ECU, etc. In other examples, the serializer circuitry 230 may be excluded from the ADAS hub 115.

The programmable circuitry 235 has first inputs, second inputs, and outputs. The first inputs of the programmable circuitry 235 are coupled to the deserializer circuitry 210 and the serializer circuitry 215. The second inputs of the programmable circuitry 235 are coupled to the deserializer circuitry 225 and the serializer circuitry 230. The outputs of the programmable circuitry 235 are coupled to the display interface circuitry 240. In some examples, the programmable circuitry 235 instantiates circuitry responsive to an execution of machine-readable instructions. In such examples, the programmable circuitry 235 may be one of a central processing unit (CPU), a graphic processing unit (GPU), multi-core processing unit (MCU), etc. Alternatively, the programmable circuitry 235 may be an application specific integrated circuit (ASIC) structured to at least one of store, process, or condition data from the deserializer circuitry 210, 225.

The display interface circuitry 240 has inputs and outputs. The inputs of the display interface circuitry 240 are coupled to the programmable circuitry 235. The outputs of the display interface circuitry 240 are coupled to the display 140. In some examples, the display interface circuitry 240 represents a display driver, which converts data from the programmable circuitry 235 to drive the display 140. In some such examples, the display interface circuitry 240 may include a port and connector specific for driving the display 140, such as a display port, a high-definition multimedia interface (HDMI) port, etc.

The serializer circuitry 245 has inputs and an output. The inputs of the serializer circuitry 245 are coupled to the sensor 255. The output of the serializer circuitry 245 is coupled to the communication channel 120A and the power regulator circuitry 250. In some examples, the serializer circuitry 245 communicates with the ADAS hub 115 using serial data streams along the communication channel 120A. An example of the serializer circuitry 245 is further illustrated and described in connection with FIG. 4.

In the example of FIG. 2, the deserializer circuitry 210 is communicatively coupled to the serializer circuitry 245 by a full-duplex wireline connection represented by the communication channel 120A. In some examples, both the deserializer circuitry 210 and the serializer circuitry 245 may receive data from or transmit data on the communication channel 120A. In such examples, the input of the deserializer circuitry 210 and the output of the serializer circuitry 245 are bi-directional. Such an example is further described in connection with FIG. 4.

The power regulator circuitry 250 has an input and an output. The input of the power regulator circuitry 250 is coupled to the communication channel 120A and the serializer circuitry 245. The output of the power regulator circuitry 250 is coupled to the sensor 255. The power regulator circuitry 250 receives power from the power supply circuitry 205. In some examples, such as in FIG. 2, the power regulator circuitry 250 receives power through the communication channel 120A. In other examples, the power supply circuitry 205 may be coupled to the power regulator circuitry 250 by a separate connection or positioned in proximity to the peripheral module 120.

The sensor 255 has an input and outputs. The input of sensor 255 is coupled to the power regulator circuitry 250. The outputs of the sensor 255 are coupled to the serializer circuitry 245. In some examples, the sensor 255 produces data corresponding to a surrounding environment. For example, in FIG. 1, the sensor 255 may be a camera positioned to capture a portion of the environment surrounding the vehicle 100. In another example, the sensor 255 may be an alternative type of sensor for corresponding to characteristics of the surrounding environment of the vehicle 100, such as obstacles.

In example operations, the power supply circuitry 205 supplies power to the power regulator circuitry 250 through the communication channel 120A. In some examples, such as the communication channel 120A being a coaxial connector, the power supply circuitry 205 and the power regulator circuitry 250 implement power over coax (POC). In such examples, the power supply circuitry 205 supplies power (POWER IN) and the power regulator circuitry 250 receives power (POWER OUT). The power regulator circuitry 250 powers the sensor 255, or more generally the peripheral module 120 based on power from the power supply circuitry 205. Similarly, the power supply circuitry 220 may utilize the communication channel 135A to supply power to the peripheral module 135.

The sensor 255 generates data corresponding to the surrounding environment. In some examples, the sensor 255 is a camera that produces multimedia data corresponding to a perspective of the surrounding environment. In another example, the sensor 255 is a lidar device that produces time of flight data corresponding to potential obstacles in the surrounding environment. In yet another example, the sensor 255 is a radar that produces beamforming data corresponding to the surrounding environment. Alternatively, the sensor 255 may be another type of sensor that produces a different type of data. In such example operations, the sensor 255 produces sensor data using multiple parallel data paths (also referred to as lines or lanes). The serializer circuitry 245 serializes data of the multiple parallel data paths to produce a serial data stream having a data rate greater than the data rate of the parallel data paths from the sensor 255. The serializer circuitry 245 transmits the serial data stream to the deserializer circuitry 210 using a front channel of the communication channel 120A, also referred to as a forward channel. Such data of the serial data stream is referred to as front channel data (DATA_{FC_0}), or forward channel data.

In example operations, the deserializer circuitry 210 receives the serial data stream after traversing the communication channel 120A. Concurrently, the deserializer circuitry 210 may transmit a serial data stream to the serializer circuitry 245 using a back-channel of the communication channel 120A. Such data is referred to as back-channel data (DATA_{BC_0}). In such examples, the front channel data has a data rate greater than the back-channel data to reduce interference. In a particular example, front channel data has a data rate in the multiple Gigabits per second (Gbs), and back-channel data has a data rate in the Megabits per second (Mbs). Simultaneous multi-directional communications along the forward channel and back-channel of the communication channel 120A are referred to as full-duplex communications. The deserializer circuitry 210 may use the back-channel of the communication channel 120A to control settings of the sensor 255 or verify reception of data on the front channel. Similarly, the peripheral module 135 and the deserializer circuitry 225 may utilize full-duplex communications along the communication channel 135A to exchange front and back-channel data (DATA_{FC_N}, DATA_{BC_N}).

In example operations, the deserializer circuitry 210 deserializes the front channel data to produce multiple parallel data paths. In some examples, the deserializer circuitry 210 may decode identifying data from the front channel data. In such examples, the serializer circuitry 215 may serialize and transmit the front channel data to external circuitry responsive to the deserializer circuitry 210 decoding identifying data corresponding to external circuitry. Advantageously, the serializer circuitry 215 allows the ADAS system 105 to be coupled to another instance of the ADAS system 105, the IVI system 110, or alternative type of data processing system.

In example operations, the programmable circuitry 235 at least one of processes, stores, or conditions the data of the multiple parallel data paths for the display 140. In some examples, the programmable circuitry 235 combines data from the peripheral modules 120, 135 prior to display. For example, the programmable circuitry 235 may stitch video streams from the peripheral modules 120, 135 to display a larger portion of the surrounding environment. In such examples, the display interface circuitry 240 structures the data from the programmable circuitry 235 to drive the display 140. In some examples, the display interface circuitry 240 is at least one of a column pixel driver or a row pixel driver. The display 140 produces a perceivable representation of the data from at least one of the peripheral modules 120, 135.

Example operations of the serializer and deserializer system of the ADAS system 105 are further described in connection with FIG. 4. Advantageously, serializing and deserializing data from the peripheral modules 120, 135 reduces the number of connections to the ADAS hub 115. Advantageously, the serial data streams are capable of accurately traversing relatively large distances across the communication channels 120A, 135A.

FIG. 3 is a block diagram of an example of the IVI system 110 of FIG. 1. The IVI system 110 of FIG. 3 includes the media source 145, the IVI driver circuitry 150, the example of the display driver 155, 170, and the displays 160, 165, 175 of FIG. 1. The example IVI driver circuitry 150 of FIG. 3 includes example programmable circuitry 320 and example serializer circuitry 330. The example display driver 155 of FIG. 3 includes example deserializer circuitry 340, example decoder circuitry 350, example display interface circuitry 360, and example serializer circuitry 370.

The programmable circuitry 320 has an input and outputs. The input of the programmable circuitry 320 is coupled to the media source 145. The outputs of the programmable circuitry 320 are coupled to the serializer circuitry 330. In some examples, the programmable circuitry 320 instantiates circuitry responsive to the execution of machine-readable instructions. In such examples, the programmable circuitry 320 may be one of a CPU, a GPU, an MCU, etc. Alternatively, the programmable circuitry 235 may be an ASIC structured to at least one of store, process, or condition data from the media source 145.

The serializer circuitry 330 has inputs, a first output, and a second output. The inputs of the serializer circuitry 330 are coupled to the programmable circuitry 320. The first output of the serializer circuitry 330 is coupled to the communication channel 155A. The second output of the serializer circuitry 330 is coupled to the communication channel 155B. In some examples, the serializer circuitry 330 communicates with the display driver 155 using serial data streams along the communication channels 155A, 155B. An example of the serializer circuitry 330 is further illustrated and described in connection with FIG. 4. Unlike the serializer circuitry 245 of FIG. 2, the serializer circuitry 330 exchanges data using multiple serial data streams along the communication channels 155A, 155B. In some examples, the serializer circuitry 330 may be illustrated and described as a plurality of instances of the serializer circuitry 330 supporting a single one of the communication channels 155A, 155B. For example, the serializer circuitry 330 may be separated into two instances of the serializer circuitry 330.

The deserializer circuitry 340 has a first input, a second input, and outputs. The first input of the deserializer circuitry 340 is coupled to the communication channel 155A. The second input of the deserializer circuitry 340 is coupled to the communication channel 155B. The outputs of the deserializer circuitry 340 are coupled to the decoder circuitry 350. In some examples, the deserializer circuitry 340 communicates with the IVI driver circuitry 150 using serial data streams along the communication channels 155A, 155B. An example of the deserializer circuitry 340 is further illustrated and described in connection with FIG. 4. Unlike the deserializer circuitry 210, 225 of FIG. 2, the deserializer circuitry 340 exchanges data using multiple serial data streams along the communication channels 155A, 155B. In some examples, the deserializer circuitry 340 may be illustrated and described as a plurality of instances of the deserializer circuitry 340 supporting a single one of the communication channels 155A, 155B. For example, the deserializer circuitry 340 may be separated into two instances of the deserializer circuitry 340, such as the deserializer circuitry 210, 225 of FIG. 2.

The decoder circuitry 350 has inputs, first outputs, and second outputs. The inputs of the decoder circuitry 350 are coupled to the deserializer circuitry 340. The first outputs of the decoder circuitry 350 are coupled to the display interface 360. The second outputs of the decoder circuitry 350 are coupled to the serializer circuitry 370. In some examples, the decoder circuitry 350 is implemented using programmable circuitry or an ASIC. In such examples, the decoder circuitry 350 is structured to route data from the deserializer circuitry 340 to at least one of the display interface 360 or the serializer circuitry 370 responsive to the decoded portions of the data. Such portions of the data from the deserializer circuitry 340 may be referred to as identifying data, which specifies one or more of the displays 160, 165, 175 to display the media on.

The display interface 360 has inputs, first outputs, and second outputs. The inputs of the display interface 360 are coupled to the decoder circuitry 350. The first outputs of the display interface 360 are coupled to the display 160. The second outputs of the display interface 360 are coupled to the display 165. In some examples, the display interface 360 drives one or more of the displays 160, 165 responsive to data from the decoder circuitry 350. In some such examples, the display interface 360 may include a port and connector specific for driving the displays, such as a display port, an HDMI port, etc. In the example of FIG. 3, the display interface 360 drives the displays 160, 165. Alternatively, the display driver 155 may include any number of display interfaces 360 for driving any number of displays, such as the displays 160, 165.

The serializer circuitry 370 has inputs, a first output, and a second output. The inputs of the serializer circuitry 370 are coupled to the decoder circuitry 350. The first output of the serializer circuitry 370 is coupled to the communication channel 155C. The second output of the serializer circuitry 370 is coupled to the communication channel 155D. In some examples, the serializer circuitry 370 communicates with the display driver 170 using serial data streams along the communication channels 155C, 155D. An example of the serializer circuitry 370 is further illustrated and described in connection with FIG. 4. Similar to the serializer circuitry 330, the serializer circuitry 370 exchanges data using multiple serial data streams along the communication channels 155C, 155D. In some examples, the serializer circuitry 370 may be illustrated and described as a plurality of instances of the serializer circuitry 370 supporting one of the communication channels 155C, 155D. For example, the serializer circuitry 370 may be separated into two instances of the serializer circuitry 370.

In example operations, the programmable circuitry 320 receives multimedia data from the media source 145. In some examples, the media source 145 is internal to the IVI system 110, such as memory storage, an ECU, a media stream, etc. In other examples, the media source 145 is external to the IVI system 110, such as a wireless connection to a service hosting a multi-media stream. The programmable circuitry 320 identifies one or more of the displays 160, 165, 175 that correspond to the data from the media source 145. In some examples, the programmable circuitry 320 encodes additional data onto the data from the media source 145 corresponding to different operations of the IVI system 110. For example, the programmable circuitry 320 adds identifying data into portions of the data from the media source 145 to specify one or more of the displays 160, 165, 175 that correspond to the media. In such examples, the identifying data may specify the one or more of the displays 160, 165, 175. The programmable circuitry 320 supplies the data to the serializer circuitry 330 for transmission to the display drivers 155, 170.

In example operations, the serializer circuitry 330 receives data from the programmable circuitry 320 on multiple parallel data paths. The serializer circuitry 330 serializes data of the multiple parallel data paths to produce a first and second serial data stream having a data rate greater than the data rate of the parallel data paths from the programmable circuitry 320. The serializer circuitry 330 transmits the first serial data stream to the deserializer circuitry 340 using a front channel of the communication channel 155A. The data of the first serial data stream is referred to as first front channel data (DATA_{FC_0}). The serializer circuitry 330 transmits the second serial data stream to the deserializer circuitry 340 using a front channel of the communication channel 155B. The data of the second serial data stream is referred to as second front channel data (DATA_{FC_1}). Advantageously, increasing the number of communication channels between the serializer circuitry 330 and the deserializer circuitry 340 increases the possible number of displays the IVI system 110 may support at a given time.

In example operations, the deserializer circuitry 340 receives the first and second serial data streams after traversing the communication channels 155A, 155B. Concurrently, the deserializer circuitry 340 may transmit a first serial data stream to the serializer circuitry 330 using a back-channel of the communication channel 155A. The data of the first serial data stream is referred to as first back-channel data (DATA_{BC_0}). Similarly, the deserializer circuitry 340 may transmit a second serial data stream to the serializer circuitry 330 using a back-channel of the communication channel 155B. The data of the second serial data stream is referred to as second back-channel data (DATA_{BC_1}). In such examples, the first and second front channel data has a data rate greater than the first and second back-channel data to reduce interference. Simultaneous multi-directional communications along the respective forward channel and back-channel of the communication channels 155A, 155B are referred to as full-duplex communications. The deserializer circuitry 340 may use the back-channel of the communication channels 155A, 155B to verify reception of the first and second front channel data, report errors to the programmable circuitry 320, etc. Similarly, the display driver 170 and the serializer circuitry 370 may utilize full-duplex communications along the communication channels 155C, 155D to exchange third and fourth front channel data (DATA_{FC_2}, DATA_{FC_3}) and third and fourth back-channel data (DATA_{BC_2}, DATA_{BC_3}).

In example operations, the deserializer circuitry 340 deserializes the first and second front channel data to produce multiple parallel data paths. The decoder circuitry 350 decodes the data from the media source 145 from the additional data from the programmable circuitry 320. The decoder circuitry 350 determines which one or more of the displays 160, 165, 175 correspond to the data from the media source 145 responsive to the decoded data. In some examples, the decoder circuitry 350 supplies the multiple parallel data paths to the serializer circuitry 370 responsive to a determination that the media does not correspond to the displays 160, 165. In such examples, the serializer circuitry 370 serializes and transmits the third and fourth front channel data to the display driver 170. Advantageously, the display driver 170 may be coupled in series with another instance of the display driver 170 by additional communication channels, such as a fifth and sixth communication channel.

In example operations, the decoder circuitry supplies the multiple parallel data paths to the display interface 360 responsive to a determination that the media from the media source 145 corresponds to at least one of the displays 160, 165. In some examples, the display interface 360 structures the data from the decoder circuitry 350 to drive one or more of the displays 160, 165. In some examples, the display interface 360 is at least one of a column pixel driver or a row pixel driver. In such examples, at least one of the displays 160, 165 produce a perceivable representation of the media from the media source 145 responsive to the display interface 360.

Example operations of the serializer and deserializer system of the IVI system 110 are further described in connection with FIG. 4. Advantageously, serializing and deserializing data from the media source 145 reduces the number of connections to one or more of the displays 160, 165, 175. Also, the serial data streams can accurately traverse relatively large distances across the communication channels 155A, 155B, 155C, 155D.

FIG. 4 is a block diagram of an example serial-deserializer (SerDes) system 400 including example deserializer circuitry 405 and example serializer circuitry 410. The example deserializer circuitry 405 of FIG. 4 includes an example serializer 415, example transmitter circuitry 420, example receiver circuitry 425, and example clock and data recovery (CDR) circuitry 430. The example CDR circuitry 430 of FIG. 4 includes example retimer circuitry 435 and an example deserializer 440. The example serializer circuitry 410 of FIG. 4 includes an example serializer 445, example transmitter circuitry 450, example receiver circuitry 455, example CDR circuitry 460, and example decoder circuitry 465. The example CDR circuitry 460 of FIG. 4 includes example retimer circuitry 470 and an example deserializer 475.

The SerDes system 400 includes an interface between the deserializer circuitry 405 and the serializer circuitry 410 in both the ADAS system 105 of FIGS. 1 and 2 and the IVI system 110 of FIGS. 1 and 3. In the example of the ADAS system 105 of FIG. 2, the deserializer circuitry 405 represents the deserializer circuitry 210 in the ADAS hub 115 and the serializer circuitry 410 represents the serializer circuitry 245 in the peripheral module 120. In the example of the IVI system 110 of FIG. 3, the deserializer circuitry 405 represents the deserializer circuitry 340 in the display driver 155. Also, in the example of the IVI system 110 of FIG. 3, the serializer circuitry 410 represents the serializer circuitry 330 in the IVI driver circuitry 150 or the serializer circuitry 370 in the display driver 155.

The deserializer circuitry 405 is coupled to the serializer circuitry 410 by the communication channel 410A. The deserializer circuitry 405 has inputs (DATA_IN_{BC}) and outputs (DATA_OUT_{FC}). The inputs and outputs of the deserializer circuitry 405 are structured to be coupled to one of the programmable circuitry 235 of FIG. 2 or the decoder circuitry 350 of FIG. 3. The inputs of the deserializer circuitry 405 receive back-channel data for transmission along the communication channel 410A. The outputs of the deserializer circuitry 405 provide front channel data from the communication channel 410A.

The serializer circuitry 410 is coupled to the deserializer circuitry 405 by the communication channel 410A. The serializer circuitry 410 has inputs (DATA_IN_{FC}) and outputs (DATA_OUT_{BC}). The inputs and outputs of the serializer circuitry 410 are structured to be coupled to one of the sensor 255 of FIG. 2 or the programmable circuitry 320 of FIG. 3. The inputs of the serializer circuitry 410 receive front channel data for transmission along the communication channel 410A. The outputs of the serializer circuitry 410 provide back-channel data from the communication channel 410A.

The serializer 415 has inputs and an output. The inputs of the serializer 415 are coupled to the inputs of the deserializer circuitry 405 (DATA_IN_{BC}). The output of the serializer 415 is coupled to the transmitter circuitry 420. In some examples, the serializer 415 is referred to as a back-channel serializer.

The transmitter circuitry 420 has an input and an output. The input of the transmitter circuitry 420 is coupled to the serializer 415. The output of the transmitter circuitry 420 is coupled to the communication channel 410A and the receiver circuitry 425. In some examples, the transmitter circuitry 420 is referred to as a back-channel transmitter.

The receiver circuitry 425 has an input and an output. The input of the receiver circuitry 425 is coupled to the communication channel 410A and the transmitter circuitry 420. The output of the receiver circuitry 425 is coupled to the CDR circuitry 430. In some examples, the receiver circuitry 425 is referred to as a front channel receiver.

The CDR circuitry 430 has an input and outputs. The input of the CDR circuitry 430 is coupled to the receiver circuitry 425. The outputs of the CDR circuitry 430 are coupled to the outputs of the deserializer circuitry 405 (DATA_OUT_{FC}). In some examples, the CDR circuitry 430 is referred to as front channel CDR circuitry.

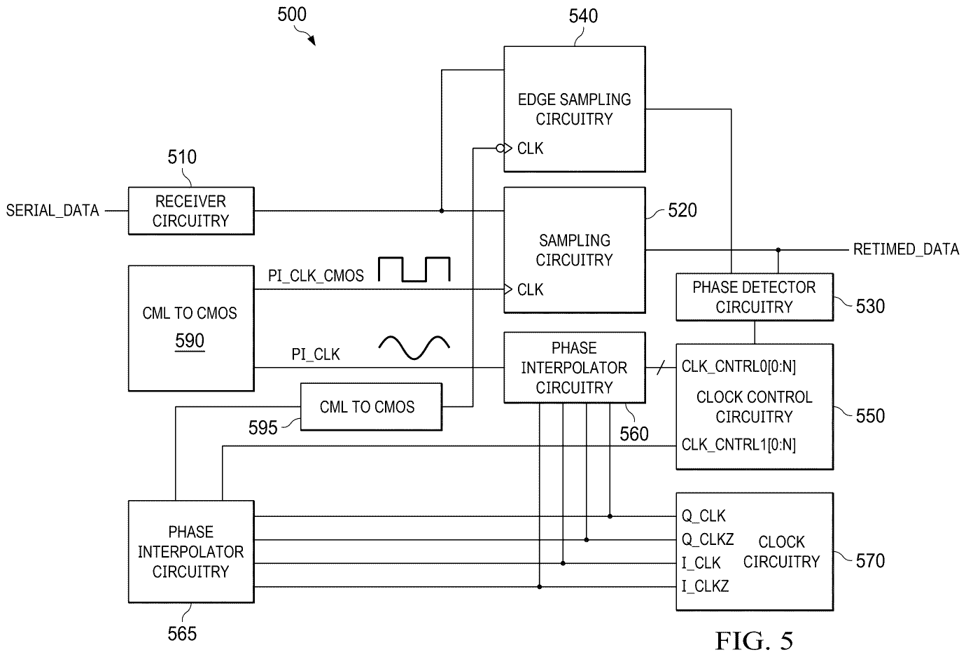

The retimer circuitry 435 has an input, a first output, and a second output. The input of the retimer circuitry 435 is coupled to the receiver circuitry 425. The first and second outputs of the retimer circuitry 435 are coupled to the deserializer 440. An example of the retimer circuitry 435 is further illustrated and described in connection with FIG. 5.

The deserializer 440 has a first input, a second input, and outputs. The first and second inputs of the deserializer 440 are coupled to the retimer circuitry 435. The outputs of the deserializer 440 are coupled to the outputs of the deserializer circuitry 405 (DATA_OUT_{FC}).

The serializer 445 has inputs and an output. The inputs of the serializer 445 are coupled to the inputs of the serializer circuitry 410 (DATA_IN_{FC}). The output of the serializer 445 is coupled to the transmitter circuitry 450. In some examples, the serializer is referred to as a front channel serializer.

The transmitter circuitry 450 has an input and an output. The input of the transmitter circuitry 450 is coupled to the serializer 445. The output of the transmitter circuitry 450 is coupled to the communication channel 410A and the receiver circuitry 455. In some examples, the transmitter circuitry 450 is referred to as a front channel transmitter. The transmitter circuitry 420, 450 may include circuitry to impedance match the communication channel 410A to reduce reflections. Also, the transmitter circuitry 420, 450 may have different bandwidths.

The receiver circuitry 455 has an input and an output. The input of the receiver circuitry 455 is coupled to the communication channel 410A and the transmitter circuitry 450. The output of the receiver circuitry 455 is coupled to the CDR circuitry 460. In some examples, the receiver circuitry 455 is referred to as a back-channel receiver.

The CDR circuitry 460 has an input and outputs. The input of the CDR circuitry 460 is coupled to the receiver circuitry 455. The outputs of the CDR circuitry 460 are coupled to the decoder circuitry 465. In some examples, the CDR circuitry 460 is referred to as back-channel CDR circuitry.

The decoder circuitry 465 has inputs and outputs. The inputs of the decoder circuitry 465 are coupled to the CDR circuitry 460. The outputs of the decoder circuitry 465 are coupled to the outputs of the serializer circuitry 410 (DATA_OUT_{BC}). In some examples, as illustrated by the dashed lines, the outputs of the CDR circuitry 460 are directly coupled to the outputs of the serializer circuitry 410 (DATA_OUT_{BC}).

The retimer circuitry 470 has an input, a first output, and a second output. The input of the retimer circuitry 470 is coupled to the receiver circuitry 455. The first and second outputs of the retimer circuitry 470 are coupled to the deserializer 475. An example of the retimer circuitry 470 is further illustrated and described in connection with FIG. 5.

The deserializer 475 has a first input, a second input, and outputs. The first and second inputs of the deserializer 475 are coupled to the retimer circuitry 470. The outputs of the deserializer 475 are coupled to the decoder circuitry 465. In some examples, as illustrated by the dashed lines, the outputs of the deserializer 475 are directly coupled to the outputs of the serializer circuitry 410 (DATA_OUT_{BC}).

In example operations, the deserializer circuitry 405 receives back-channel data (DATA_{BC}) via multiple data paths from an external data source, such as the programmable circuitry 235 or the decoder circuitry 350. The serializer 415 produces a back-channel serial data stream responsive to the back-channel data. The transmitter circuitry 420 transmits the back-channel data to the serializer circuitry 410 across the communication channel 410A. Similarly, the serializer circuitry 410 receives front channel data (DATA_{FC}) via multiple data paths from an external data source, such as the sensor 255 or the programmable circuitry 320. The serializer 445 produces a front channel serial data stream responsive to the front channel data. The transmitter circuitry 450 transmits the front channel data to the deserializer circuitry 405 across the communication channel 410A. In some examples, the data rates of the transmissions of the front and back-channel data are different to prevent interference. In some examples, the bandwidth of the transmitter circuitry 420, which transmits the back-channel data, is modified to reduce non-linear gain contributions of the communication channel 410A. Advantageously, the serializers 415, 445 and the transmitter circuitry 420, 450 support full-duplex data transmissions along the communication channel 410A.

In example operations, the deserializer circuitry 405 receives the front channel data (DATA_{FC}) after propagating along the communication channel 410A. The receiver circuitry 425 produces a serial data stream representing the front channel data responsive to signals from the communication channel 410A. In some examples, the receiver circuitry 425 isolates the communication channel 410A from the CDR circuitry 430. The deserializer circuitry 405 may include echo cancelation circuitry to reduce contributions of the back-channel data from signals received by the transmitter circuitry 420. Similarly, the serializer circuitry 410 receives the back-channel data (DATA_{BC}) after propagating along the communication channel 410A. The receiver circuitry 455 produces a serial data stream representing the back-channel data responsive to signals from the communication channel 410A. In some examples, the receiver circuitry 425 isolates the communication channel 410A from the CDR circuitry 430. The serializer circuitry 410 may include echo cancelation circuitry to reduce contributions of the front channel data from signals received by the transmitter circuitry 450. Also, the receiver circuitry 425, 455 terminate currents of the communication channel 410A.

In example operations, the CDR circuitry 430 receives the front channel data from the receiver circuitry 425. The retimer circuitry 435 retimes the front channel data to produce retimed front channel data (RETIMED_DATA). The retimer circuitry 435 produces a clock signal (CLK), which represents an accurate sampling time of the retimed front channel data. The deserializer 440 receives the retimed front channel data and the clock signal from the retimer circuitry 435. The deserializer 440 produces multiple parallel data paths representing the front channel data. The outputs of the deserializer circuitry 405 provide the front channel data to external circuitry, such as the programmable circuitry 235 or the decoder circuitry 350. Similarly, the CDR circuitry 460 receives the back-channel data from the receiver circuitry 455. The retimer circuitry 435 produces retimed back-channel data and a clock signal responsive to the retiming of the back-channel data to the clock signal. The deserializer 475 receives the retimed back-channel data and the clock signal from the retimer circuitry 470. The deserializer 475 produces multiple parallel data paths representing the back-channel data. In some such example operations, the decoder circuitry 465 decodes portions of the back-channel data prior to the outputs of the serializer circuitry 410 supplying the back-channel data to external circuitry, such as the sensor 255 or the programmable circuitry 320.

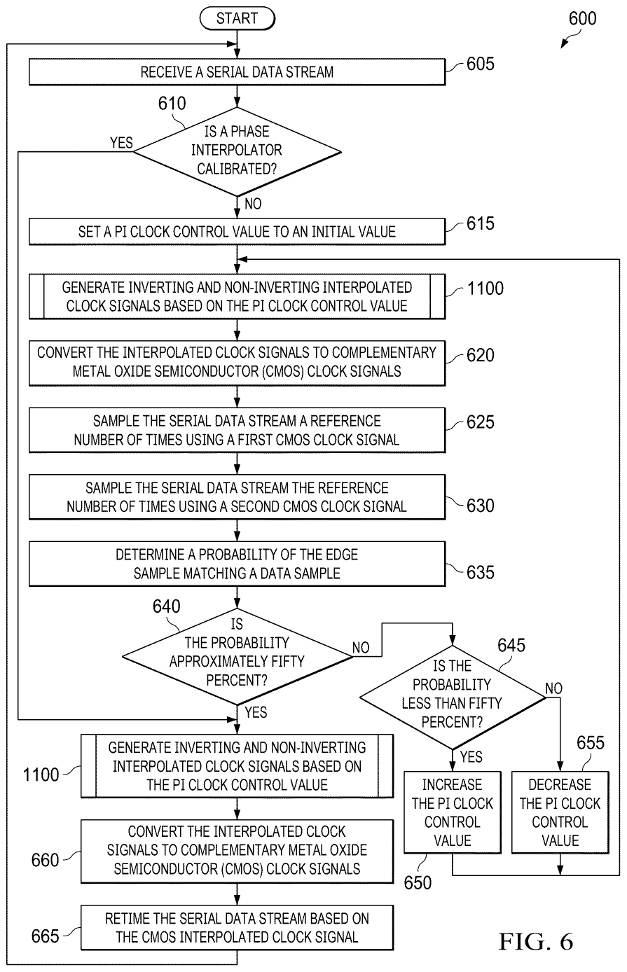

Example operations of the retimer circuitry 435, 470 are further illustrated and described in connection with FIGS. 5 and 6. Advantageously, serializing and deserializing front and back-channel data reduces the number of connections that need to traverse relatively large distances of the communication channel 410A. Advantageously, the serial data streams are capable of accurately traversing relatively large distances across the communication channels 410A.

FIG. 5 is a block diagram of example retimer circuitry 500, which is an example of the retimer circuitry 435, 470 of FIG. 4. The retimer circuitry 500 of FIG. 5 includes example receiver circuitry 510, example sampling circuitry 520, example phase detector circuitry 530, example edge sampling circuitry 540, example clock control circuitry 550, first example phase interpolator (PI) circuitry 560, second example PI circuitry 565, example clock circuitry 570, first example current mode logic (CML) to complementary metal oxide semiconductor (CMOS) converter circuitry 590, and second example CML to CMOS converter circuitry 595.

The retimer circuitry 500 has an input, a first output, and a second output. The input of the retimer circuitry 500 receives a serial data stream (SERIAL_DATA). The first output of the retimer circuitry 500 provides a retimed data stream (RETIMED_DATA). The second output of the retimer circuitry 500 provides a clock signal (CLK).

The receiver circuitry 510 has an input and an output. The input of the receiver circuitry 510 is coupled to the input of the retimer circuitry 500. The output of the receiver circuitry 510 is coupled to the sampling circuitry 520, 540. In some examples, the receiver circuitry 510 is external to the retimer circuitry 500. For example, in FIG. 4, the receiver circuitry 425 corresponds to the receiver circuitry 510 or the retimer circuitry 435.

The sampling circuitry 520 has a first input, a second input, and an output. The first input of the sampling circuitry 520 (also referred to as a data input) is coupled to the receiver circuitry 510 and the sampling circuitry 540. The second input of the sampling circuitry 520 (also referred to as a clock input) is coupled to the sampling circuitry 540, the CML to CMOS converter circuitry 590, and the second output of the retimer circuitry 500. The output of the sampling circuitry 520 is coupled to the phase detector circuitry 530 and the first output of the retimer circuitry 500. In some examples, the sampling circuitry 520 is a latch or flip-flop. Alternatively, the sampling circuitry 520 may be an alternative type of sample and hold circuitry.

The phase detector circuitry 530 has a first input, a second input, and an output. The first input of the phase detector circuitry 530 is coupled to the sampling circuitry 520 and the first output of the retimer circuitry 500. The second input of the phase detector circuitry 530 is coupled to the sampling circuitry 540. The output of the phase detector circuitry 530 is coupled to the clock control circuitry 550.

The sampling circuitry 540 has a first input, a second input, and an output. The first input of the sampling circuitry 540 (also referred to as a data input) is coupled to the receiver circuitry 510 and the sampling circuitry 520. The second input of the sampling circuitry 540 (also referred to as an inverting clock input) is coupled to the sampling circuitry 520, the CML to CMOS converter circuitry 595 and the second output of the retimer circuitry 500. The output of the sampling circuitry 540 is coupled to the phase detector circuitry 530. In some examples, the sampling circuitry 540 is a latch or flip-flop. Alternatively, the sampling circuitry 540 may be an alternative type of sample and hold circuitry.

The clock control circuitry 550 has an input, first outputs, and second outputs. The input of the clock control circuitry 550 is coupled to the phase detector circuitry 530. The first outputs of the clock control circuitry 550 (CLK_CNTRL0[0:N]) are coupled to the PI circuitry 560. The second outputs of the clock control circuitry 550 (CLK_CNTRL1[0:N]) are coupled to the PI circuitry 565.

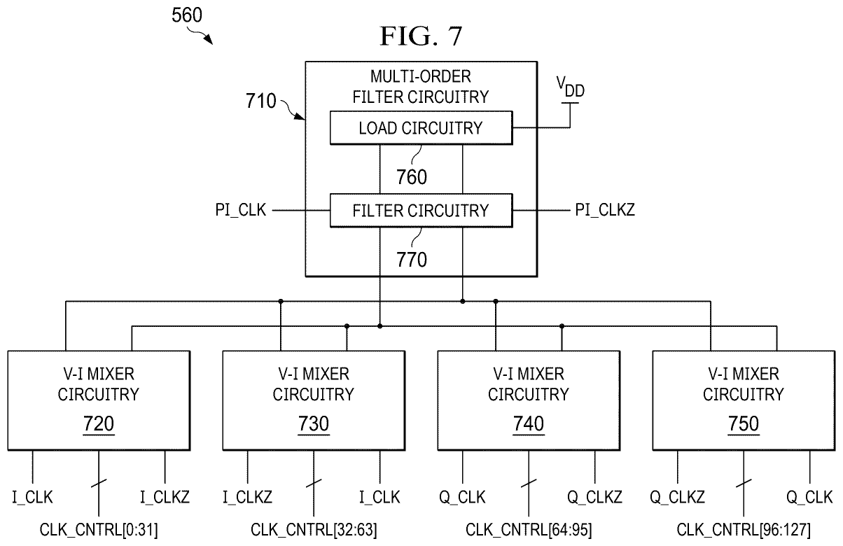

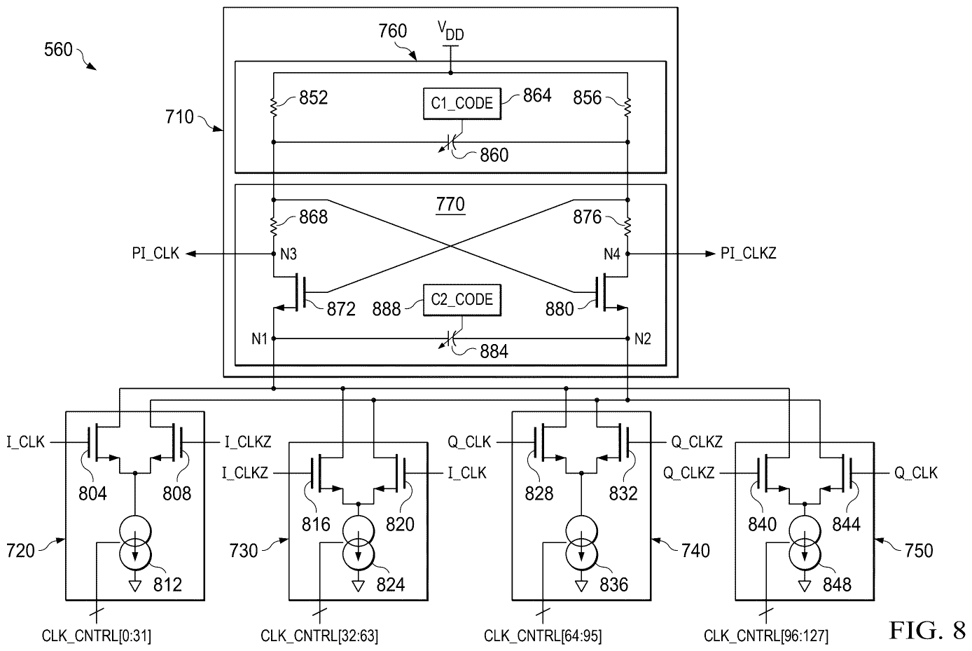

The PI circuitry 560 has first inputs, second inputs, and an output. The first inputs of the PI circuitry 560 are coupled to the clock control circuitry 550. The second inputs of the PI circuitry 560 are coupled to the clock circuitry 570 and the PI circuitry 565. The output of the PI circuitry 560 is coupled to the CML to CMOS converter circuitry 590. Examples of the PI circuitry 560 are further illustrated and described in connection with FIGS. 7 and 8.

The PI circuitry 565 has first inputs, second inputs, and an output. The first inputs of the PI circuitry 565 are coupled to the clock control circuitry 550. The second inputs of the PI circuitry 565 are coupled to the clock circuitry 570 and the PI circuitry 560. The output of the PI circuitry 565 is coupled to the CML to CMOS converter circuitry 595. Examples of the PI circuitry 565 are further illustrated and described in connection with FIGS. 7 and 8.

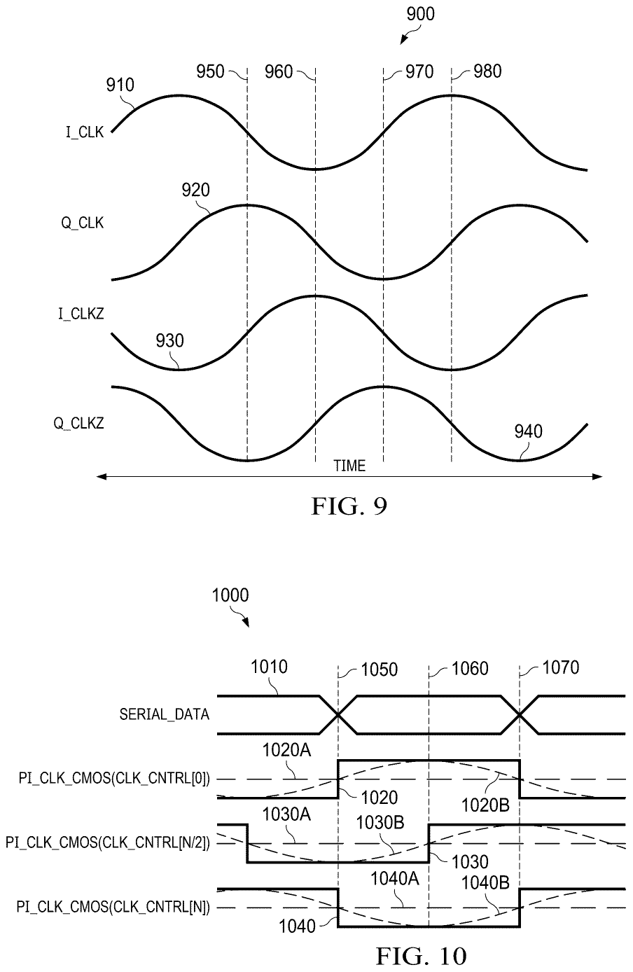

The clock circuitry 570 has a first clock output (I_CLK), a first inverted clock output (I_CLKZ), a second clock output (Q_CLK), and a second inverted clock output (Q_CLKZ) coupled to the PI circuitry 560, 565. Example operations of the clock circuitry 570 are illustrated and described in connection with FIG. 9.

The CML to CMOS converter circuitry 590 has an input and an output. The input of the CML to CMOS converter circuitry 590 is coupled to the PI circuitry 560. The output of the CML to CMOS converter circuitry 590 is coupled to the sampling circuitry 520 and the second output of the retimer circuitry 500. In some examples, the CML to CMOS converter circuitry 590 is a Schmitt trigger. Alternatively, the CML to CMOS converter circuitry 590 is another form of conversion circuitry.

The CML to CMOS converter circuitry 595 has an input and an output. The input of the CML to CMOS converter circuitry 595 is coupled to the PI circuitry 565. The output of the CML to CMOS converter circuitry 595 is coupled to the sampling circuitry 540. In some examples, the CML to CMOS converter circuitry 595 is a Schmitt trigger. Alternatively, the CML to CMOS converter circuitry 595 is another form of conversion circuitry.

FIG. 6 is a flowchart representative of example machine-readable instructions or example operations 600 that may be at least one of executed, instantiated, or performed using an example implementation of the retimer circuitry 435, 470, 500 of FIGS. 4 and 5. The example operation 600 of FIG. 6 begin at Block 605, at which the receiver circuitry 510 of FIG. 5 receives a serial data stream. In some examples, the retimer circuitry 435, 470, 500 is a part of a communication system, such as the ADAS system 105 of FIGS. 1 and 2, the IVI system 110 of FIGS. 1 and 3, or the SerDes system 400 of FIG. 4. In example operations, the receiver circuitry 510 receives a serial data stream representing sequential digital bits having a data rate. An example of a serial data stream is illustrated and described in connection with FIG. 9.

The clock control circuitry 550 of FIG. 5 determines if the phase interpolator is calibrated. (Block 610). In example operations, prior to normal operations, the clock control circuitry 550 determines clock control values (also referred to as control values) for the PI circuitry 560, 565. The PI circuitry 560 produces a first PI clock signal responsive to a first clock control value (CLK_CNTRL0[0:N]) from the clock control circuitry 550. The first clock control value sets a phase of the first PI clock signal (PI_CLK) from the PI circuitry 560. Similarly, the PI circuitry 565 produces a second PI clock signal responsive to a second clock control value (CLK_CNTRL1[0:N]) from the clock control circuitry 550. The second clock control value sets a phase of the second PI clock signal (PI_CLK) from the PI circuitry 565.

After calibration operations, as further described below, the clock control circuitry 550 calibrates the phase of the PI clock signals to reduce sampling errors of the sampling circuitry 520. Advantageously, calibrating the phase of the PI clock signal reduces retiming issues, such as inter-symbol interference (ISI), jitter, etc. In some examples, the clock control circuitry 550 determines to calibrate the PI circuitry 560, 565 responsive to at least one of a power up of the retimer circuitry 500, a periodic interval, or an external calibration indication.

If the clock control circuitry 550 determines that the phase interpolator is not calibrated (e.g., Block 610 returns a result of NO), the clock control circuitry 550 sets a PI clock control value to an initial value. (Block 615). In example operations, the clock control circuitry 550 sets the phase of the PI clock signal of the PI circuitry 560 responsive to the first clock control value. In such example operations, the possible states of the first clock control value correspond to specific phases of the PI clock signal of the PI circuitry 560. In some examples, the PI circuitry 560 evenly divides the possible values of the clock control value linearly by the possible states of the clock control value. For example, if the clock control circuitry 550 provides an eight-bit clock control value, the PI circuitry 560 sets the phase of the PI clock signal to one of two-hundred and fifty-six potential phases. In such examples, if the two-hundred and fifty-six potential phases are evenly distributed across the potential one-hundred and eighty possible degrees, the PI circuitry 560 is considered to have good linearity. In some examples, the clock control circuitry 550 begins calibrations operations by initializing the first clock control value to a value corresponding to a ninety-degree phase. Alternatively, the clock control circuitry 550 may begin calibration operations with an initial clock control value corresponding to any phase.

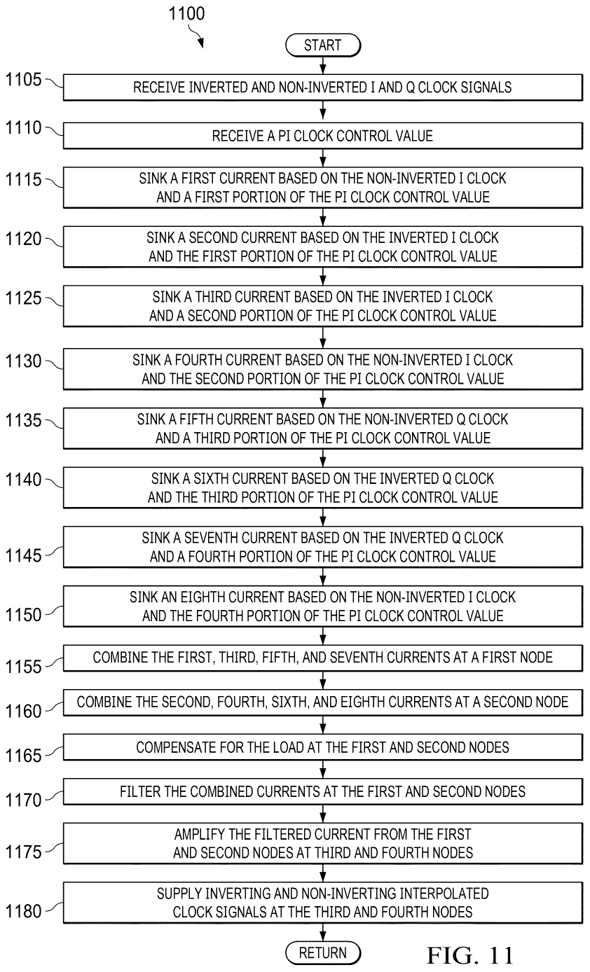

The PI circuitry 560 of FIG. 5 generates inverting and non-inverting interpolated clock signals based on the PI clock control value. (Operations 1100 of FIG. 11). In example operations, as further illustrated and described in connection with FIG. 11, the PI circuitry 560, 565 mixes currents of in-phase and quadrature clock signals (I_CLK, Q_CLK) from the clock circuitry 570 of FIG. 5. In such example operations, the PI circuitry 560, 565 determines the magnitude of contributions of the in-phase and quadrature clock signals to the PI clock signal (PI_CLK) responsive to the clock control values. Example mixing of the in-phase and quadrature clock signals are further illustrated and described in connection with FIGS. 8, 10, and 11. Concurrently, the PI circuitry 560, 565 filters the contributions of the in-phase and quadrature clock signals to produce the PI clock signal as a CML signal (e.g., a sinusoidal signal). Advantageously, mixing currents of the in-phase and quadrature clock signals to produce a CML signal filters second harmonic noise. Advantageously, filtering the second harmonic noise reduces phase errors of the PI clock signal at the PI clock outputs of the PI circuitry 560, 565. Example operations of the PI circuitry 560, 565 are further illustrated and described in connection with FIG. 11.

The CML to CMOS converter circuitry 590 of FIG. 5 converts the interpolated clock signals to CMOS clock signals. (Block 620). In example operations, the PI circuitry 560 generates the PI clock signal as a CML clock signal having a phase corresponding to the clock control value from the clock controller circuitry 550. In such example operations, the CML to CMOS converter circuitry 590 converts the CML clock signal to a CMOS clock signal, such as a PWM signal. In some examples, the CML to CMOS converter circuitry 590 may be illustrated or described as a Schmit trigger. In other examples, the CML to CMOS converter circuitry 590 is another type of converter or comparison circuitry.

The sampling circuitry 520 of FIG. 5 samples the serial data stream a reference number of times using a first CMOS clock signal. (Block 625). In example operations, the sampling circuitry 520 samples the logic level of the serial data stream responsive to edges of the CMOS PI clock signal from the CML to CMOS converter circuitry 590. In some examples, the sampling circuitry 520 samples the serial data stream by latching the logical state of the serial data stream at a rising edge of the CMOS PI clock signal. The output of the sampling circuitry 520 may be referred to as a data output. In such example operations, the sampling circuitry 520 periodically samples the serial data stream responsive to subsequent edges of the CMOS PI clock signal.

The sampling circuitry 540 of FIG. 5 samples the serial data stream the reference number of times using a second CMOS clock signal. (Block 630). In example operations, the sampling circuitry 540 samples the logic level of the serial data stream responsive to edges of the CMOS PI clock signal from the CML to CMOS converter circuitry 595. Unlike the sampling circuitry 520, the sampling circuitry 540 samples the serial data stream on a CMOS PI clock signal having a different phase. For example, if the sampling circuitry 520 samples the serial data stream using a ninety-degree offset CMOS PI clock signal, the sampling circuitry 540 samples the serial data stream using a two-hundred and seventy degree offset CMOS PI clock signal. Similar to the sampling circuitry 520, the sampling circuitry 540 samples the serial data stream by latching the logical state of the serial data stream. The output of the sampling circuitry 540 may be referred to as an edge output. In such example operations, the sampling circuitry 540 periodically samples the serial data stream responsive to subsequent edges of the CMOS PI clock signal.

The phase detector circuitry 530 of FIG. 5 determines a probability of an edge sample matching a data sample. (Block 635). In example operations, the phase detector circuitry 530 compares the logical state of the data output of the sampling circuitry 520 to the edge output of the sampling circuitry 540 across a plurality of samples. For example, the phase detector circuitry 530 determines a reference number of samples, such as one hundred samples, that the data output matches the edge output. In such example operations, the phase detector circuitry 530 determines a probability of the outputs of the sampling circuitry 520, 540 matching as a ratio of the determined reference number over the reference number of samples.

The clock control circuitry 550 determines if the probability is approximately fifty percent. (Block 640). In example operations, the clock control circuitry 550 determines the probability of the data and edge outputs of the sampling circuitry 520, 540 matching responsive to the ratio from the phase detector circuitry 530. In such example operations, the clock control circuitry 550 compares the ratio to one-half to determine if the probability of the data and edge outputs matching. Alternatively, the clock control circuitry 550 may compare the ratio to a different value or range of acceptable values. Advantageously, sampling the serial data stream with a fifty percent probability of the data and edge outputs matching increases a resistance of the sampling circuitry 520 to ISI and jitter. Advantageously, increasing the resistance of the sampling circuitry 520 to ISI and jitter increases accuracy of the retimed data stream.

If the clock control circuitry 550 determines that the probability is not approximately fifty percent (e.g., Block 640 returns a result of NO), the clock control circuitry 550 determines if the probability is less than fifty percent. (Block 645). In example operations, if the ratio of the data and edge outputs of the sampling circuitry 520, 540 across the reference number of samples is less than fifty percent, the clock control circuitry 550 determines whether to increase or decrease the phase of the PI circuitry 560. In such example operations, the clock control circuitry 550 controls the phase of the PI clock signal of the PI circuitry 560 using the clock control value.

If the clock control circuitry 550 determines that the probability is less than fifty percent (e.g., Block 645 returns a result of YES), the clock control circuitry 550 increases the PI control value. (Block 650). In example operations, if the clock control circuitry 550 determines that the data and edge outputs of the sampling circuitry 520, 540 are less likely to match (e.g., less than a one-half or fifty percent ratio), the clock control circuitry 550 adjusts the clock control value to increase the phase of the PI clock output of the PI circuitry 560. In such example operations, the data and edge outputs of the sampling circuitry 520, 540 are less likely to match if sampling different data points of the serial data stream. Advantageously, edges of the PI clock output of the PI circuitry 560 approach a midpoint between different data points responsive to increasing the phase.

If the clock control circuitry 550 determines that the probability is greater than fifty percent (e.g., Block 645 returns a result of NO), the clock control circuitry 550 decreases the PI control value. (Block 655). In example operations, if the clock control circuitry 550 determines that the data and edge outputs of the sampling circuitry 520, 540 are more likely to match (e.g., more than one-half or fifty percent ratio), the clock control circuitry 550 adjusts the clock control value to decrease the phase of the PI clock output of the PI circuitry 560. In such example operations, the data and edge outputs of the sampling circuitry 520, 540 are more likely to match if sampling different data points of the serial data stream. Advantageously, edges of the PI clock output of the PI circuitry 560 approach a midpoint between different data points responsive to decreasing the phase. Control proceeds to return to the operations 1100.

If the clock control circuitry 550 determines that the phase interpolator is calibrated (e.g., Block 610 returns a result of YES) or the clock control circuitry 550 determines that the probability is approximately fifty percent (e.g., Block 640 returns a result of YES), the PI circuitry 560 generates inverting and non-inverting interpolated clock signals based on the PI clock control value. (The operations 1100 of FIG. 11). In example operations, as further illustrated and described in connection with FIG. 11, the PI circuitry 560 mixes currents of in-phase and quadrature clock signals (I_CLK, Q_CLK) from the clock circuitry 570. In such example operations, the PI circuitry 560 determines the magnitude of contributions of the in-phase and quadrature clock signals to the PI clock signal (PI_CLK) responsive to the clock control value. Example mixing of the in-phase and quadrature clock signals are further illustrated and described in connection with FIGS. 8, 10, and 11. Concurrently, the PI circuitry 560 filters the contributions of the in-phase and quadrature clock signals to produce the PI clock signal as a CML signal (e.g., a sinusoidal signal). Advantageously, mixing currents of the in-phase and quadrature clock signals to produce a CML signal filters second harmonic noise. Advantageously, filtering the second harmonic noise reduces phase errors of the PI clock signal at the PI clock output of the PI circuitry 560. Example operations of the PI circuitry 560 are further illustrated and described in connection with FIG. 11.

The CML to CMOS converter circuitry 590 converts the interpolated clock signals to CMOS clock signals. (Block 660). In example operations, the PI circuitry 560 generates the PI clock signal as a CML signal having a phase corresponding to the clock control value from the clock controller circuitry 550. In such example operations, the CML to CMOS converter circuitry 590 converts the CML PI clock signal to a CMOS PI clock signal, such as a square wave. In some examples, the CML to CMOS converter circuitry 590 may be illustrated or described as a Schmit trigger. In other examples, the CML to CMOS converter circuitry 590 is a different type of converter or comparison circuitry.

The sampling circuitry 520 retimes the serial data stream based on the CMOS interpolated clock signal. (Block 665). In example operations, the sampling circuitry 520 produces a retimed data stream responsive to sampling the serial data stream using edges of the CMOS PI clock signal. In such example operations, the retimed data stream corresponds to the CMOS PI clock signal from the CML to CMOS converter circuitry 590.

Control proceeds to return to Block 605. Example methods are described with reference to the flowchart illustrated in FIG. 6. However, many other methods of implementing the retimer circuitry 435, 470, 500 of FIGS. 4 and 5 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 7 is a block diagram of an example of the PI circuitry 560 of FIG. 5. The example PI circuitry 560 of FIG. 7 includes example multi-order filter circuitry 710, first example voltage-to-current (V-I) circuitry 720, second example V-I circuitry 730, third example V-I circuitry 740, and fourth example V-I circuitry 750. The example multi-order filter circuitry 710 of FIG. 7 includes example load circuitry 760 and example filter circuitry 770.

The PI circuitry 560 has a first clock input, a first inverted clock input, a second clock input, a second inverted clock input, control inputs, a PI clock output, and an inverted PI clock output. The first clock input of the PI circuitry 560 is structured to be coupled to the clock circuitry 570, which provides an in-phase clock signal (I_CLK). The first inverted clock input of the PI circuitry 560 is structured to be coupled to the clock circuitry 570, which provides an inverted in-phase clock signal (I_CLKZ). The second clock input of the PI circuitry 560 is structured to be coupled to the clock circuitry 570, which provides a quadrature clock signal (Q_CLK). The second inverted clock input of the PI circuitry 560 is structured to be coupled to the clock circuitry 570, which provides an inverted quadrature clock signal (Q_CLKZ). Such in-phase and quadrature clock signals are referred to as IQ clock signals. Examples of the IQ clock signals are illustrated and described in connection with FIG. 9. The control inputs of the PI circuitry 560 are structured to be coupled to the clock control circuitry 550, which provides clock control value (CLK_CNTRL[0: N]). The PI clock output of the PI circuitry 560 is structured to be coupled to the CML to CMOS converter circuitry 590. The PI clock output provides a PI clock signal (PI_CLK). The inverted PI clock output of the PI circuitry 560 provides an inverted PI clock signal (PI_CLKZ).

The multi-order filter circuitry 710 has a first input, a second input, a first output, and a second output. The first input of the multi-order filter circuitry 710 is coupled to the V-I circuitry 720, 730, 740, 750. The second input of the multi-order filter circuitry 710 is coupled to the V-I circuitry 720, 730, 740, 750. The first output of the multi-order filter circuitry 710 provides the PI clock signal (PI_CLK). The second output of the multi-order filter circuitry 710 provides the inverted PI clock signal (PI_CLKZ). In some examples, the multi-order filter circuitry 710 is referred to as Bi-quad filter circuitry, which is a second order filter. Alternatively, the multi-order filter circuitry 710 includes different-order of filter. A schematic example of the multi-order filter circuitry 710 is further illustrated and described in connection with FIG. 8.

The V-I circuitry 720 has a first input, a second input, control inputs, a first output, and a second output. The first input of the V-I circuitry 720 is coupled to the first clock input of the PI circuitry 560 (to receive I_CLK). The second input of the V-I circuitry 720 is coupled to the first inverted clock input of the PI circuitry 560 (to receive I_CLKZ). The control input of the V-I circuitry 720 is coupled to a first portion of the control inputs of the PI circuitry 560 (to receive CLK_CNTRL[0:31]). The first output of the V-I circuitry 720 is coupled to the V-I circuitry 730, 740, 750 and the filter circuitry 770. The second output of the V-I circuitry 720 is coupled to the V-I circuitry 730, 740, 750 and the filter circuitry 770. A schematic example of the V-I circuitry 720 is further illustrated and described in connection with FIG. 8.

The V-I circuitry 730 has a first input, a second input, control inputs, a first output, and a second output. The first input of the V-I circuitry 730 is coupled to the first clock input of the PI circuitry 560 (to receive I_CLK). The second input of the V-I circuitry 730 is coupled to the first inverted clock input of the PI circuitry 560 (to receive I_CLKZ). The control input of the V-I circuitry 730 is coupled to a second portion of the control inputs of the PI circuitry 560 (to receive CLK_CNTRL[32:64]). The first output of the V-I circuitry 730 is coupled to the V-I circuitry 720, 740, 750 and the filter circuitry 770. The second output of the V-I circuitry 730 is coupled to the V-I circuitry 720, 740, 750 and the filter circuitry 770. A schematic example of the V-I circuitry 730 is further illustrated and described in connection with FIG. 8.

The V-I circuitry 740 has a first input, a second input, control inputs, a first output, and a second output. The first input of the V-I circuitry 740 is coupled to the second clock input of the PI circuitry 560 (to receive Q_CLK). The second input of the V-I circuitry 740 is coupled to the second inverted clock input of the PI circuitry 560 (to receive Q_CLKZ). The control input of the V-I circuitry 740 is coupled to a third portion of the control inputs of the PI circuitry 560 (CLK_CNTRL[64:95]). The first output of the V-I circuitry 740 is coupled to the V-I circuitry 720, 730, 750 and the filter circuitry 770. The second output of the V-I circuitry 740 is coupled to the V-I circuitry 720, 730, 750 and the filter circuitry 770. A schematic example of the V-I circuitry 740 is further illustrated and described in connection with FIG. 8.

The V-I circuitry 750 has a first input, a second input, control inputs, a first output, and a second output. The first input of the V-I circuitry 750 is coupled to the second clock input of the PI circuitry 560 (Q_CLK). The second input of the V-I circuitry 750 is coupled to the second inverted clock input of the PI circuitry 560 (Q_CLKZ). The control input of the V-I circuitry 750 is coupled to a fourth portion of the control inputs of the PI circuitry 560 (CLK_CNTRL[96:127]). The first output of the V-I circuitry 750 is coupled to the V-I circuitry 720, 730, 740 and the filter circuitry 770. The second output of the V-I circuitry 750 is coupled to the V-I circuitry 720, 730, 740 and the filter circuitry 770. A schematic example of the V-I circuitry 750 is further illustrated and described in connection with FIG. 8.

The load circuitry 760 has a first terminal, a second terminal, and a third terminal. The first terminal of the load circuitry 760 is coupled to a supply terminal, which provides a supply voltage (e.g., V_{DD}, AVDD, etc.). The second and third terminals of the load circuitry 760 are coupled to the filter circuitry 770. A schematic example of the load circuitry 760 is further illustrated and described in connection with FIG. 8.

The filter circuitry 770 has a first terminal, a second terminal, a third terminal, a fourth terminal, a fifth terminal, and a sixth terminal. The first and second terminals of the filter circuitry 770 are coupled to the V-I circuitry 720, 730, 740, 750. The third and fourth terminals of the filter circuitry 770 are coupled to the load circuitry 760. The fifth terminal of the filter circuitry 770 is coupled to the PI clock output of the PI circuitry 560 (PI_CLK). The sixth terminal of the filter circuitry 770 is coupled to the inverted PI clock output of the PI circuitry 560 (PI_CLKZ). A schematic example of the filter circuitry 770 is further illustrated and described in connection with FIG. 8. Example operations of the PI circuitry 560 are illustrated and described in connection with FIG. 11.

FIG. 8 is a schematic diagram of an example of the PI circuitry 560 of FIGS. 5 and 6. The PI circuitry 560 of FIG. 8 includes the multi-order filter circuitry 710 and the V-I circuitry 720, 730, 740, 750. The multi-order filter circuitry 710 of FIG. 8 includes the load circuitry 760 and the filter circuitry 770. The V-I circuitry 720 of FIG. 8 includes a first example transistor 804, a second example transistor 808, and example current source circuitry 812. The V-I circuitry 730 of FIG. 8 includes a first example transistor 816, a second example transistor 820, and example current source circuitry 824. The V-I circuitry 740 of FIG. 8 includes a first example transistor 828, a second example transistor 832, and example current source circuitry 836. The V-I circuitry 750 of FIG. 8 includes a first example transistor 840, a second example transistor 844, and example current source circuitry 848. The load circuitry 760 of FIG. 8 includes a first example resistor 852, a second example resistor 856, an example capacitor 860, and an example trim register 864. The filter circuitry 770 of FIG. 8 includes a first example resistor 868, a first example transistor 872, a second example resistor 876, a second example transistor 880, an example capacitor 884, and an example trim register 888.

The transistor 804 has a first terminal, a second terminal, and a control terminal. The first terminal of the transistor 804 is coupled to the transistors 816, 828, 840, 872 and the capacitor 884. The second terminal of the transistor 804 is coupled to the transistor 808 and the current source circuitry 812. The control terminal of the transistor 804 is coupled to the first clock input of the PI circuitry 560 (I_CLK).

The transistor 808 has a first terminal, a second terminal, and a control terminal. The first terminal of the transistor 808 is coupled to the transistors 820, 832, 844, 880 and the capacitor 884. The second terminal of the transistor 808 is coupled to the transistor 804 and the current source circuitry 812. The control terminal of the transistor 808 is coupled to the first inverted clock input of the PI circuitry 560 (I_CLKZ).

The current source circuitry 812 has a first terminal, a second terminal, and a control input. The first terminal of the current source circuitry 812 is coupled to the transistors 804, 808. The second terminal of the current source circuitry 812 is coupled to a common terminal, which provides a common potential (e.g., ground, AVSS, etc.). The control input of the current source circuitry 812 is coupled to a first portion of the control inputs of the PI circuitry 560 (CLK_CNTRL[0:31]).

The transistor 816 has a first terminal, a second terminal, and a control terminal. The first terminal of the transistor 816 is coupled to the transistors 804, 828, 840, 872 and the capacitor 884. The second terminal of the transistor 816 is coupled to the transistor 820 and the current source circuitry 824. The control terminal of the transistor 816 is coupled to the first inverted clock input of the PI circuitry 560 (I_CLKZ).

The transistor 820 has a first terminal, a second terminal, and a control terminal. The first terminal of the transistor 820 is coupled to the transistors 808, 832, 844, 880 and the capacitor 884. The second terminal of the transistor 820 is coupled to the transistor 816 and the current source circuitry 824. The control terminal of the transistor 820 is coupled to the first clock input of the PI circuitry 560 (I_CLK).

The current source circuitry 824 has a first terminal, a second terminal, and a control input. The first terminal of the current source circuitry 824 is coupled to the transistors 816, 820. The second terminal of the current source circuitry 824 is coupled to the common terminal, which provides the common potential. The control input of the current source circuitry 824 is coupled to a second portion of the control inputs of the PI circuitry 560 (CLK_CNTRL[32:63]).

The transistor 828 has a first terminal, a second terminal, and a control terminal. The first terminal of the transistor 828 is coupled to the transistors 804, 816, 840, 872 and the capacitor 884. The second terminal of the transistor 828 is coupled to the transistor 832 and the current source circuitry 836. The control terminal of the transistor 828 is coupled to the second clock input of the PI circuitry 560 (Q_CLK).

The transistor 832 has a first terminal, a second terminal, and a control terminal. The first terminal of the transistor 832 is coupled to the transistors 808, 820, 844, 880 and the capacitor 884. The second terminal of the transistor 832 is coupled to the transistor 828 and the current source circuitry 836. The control terminal of the transistor 832 is coupled to the second inverted clock input of the PI circuitry 560 (Q_CLKZ).

The current source circuitry 836 has a first terminal, a second terminal, and a control input. The first terminal of the current source circuitry 836 is coupled to the transistors 828, 832. The second terminal of the current source circuitry 836 is coupled to the common terminal, which provides the common potential. The control input of the current source circuitry 836 is coupled to a third portion of the control inputs of the PI circuitry 560 (CLK_CNTRL[64:95]).

The transistor 840 has a first terminal, a second terminal, and a control terminal. The first terminal of the transistor 840 is coupled to the transistors 804, 816, 828, 872 and the capacitor 884. The second terminal of the transistor 840 is coupled to the transistor 844 and the current source circuitry 848. The control terminal of the transistor 840 is coupled to the second inverted clock input of the PI circuitry 560 (Q_CLKZ).

The transistor 844 has a first terminal, a second terminal, and a control terminal. The first terminal of the transistor 844 is coupled to the transistors 808, 820, 832, 880 and the capacitor 884. The second terminal of the transistor 844 is coupled to the transistor 840 and the capacitor 884. The control terminal of the transistor 844 is coupled to the second clock input of the PI circuitry 560 (Q_CLK).

The current source circuitry 848 has a first terminal, a second terminal, and a control input. The first terminal of the current source circuitry 848 is coupled to the transistors 840, 844. The second terminal of the current source circuitry 848 is coupled to the common terminal, which provides the common potential. The control input of the current source circuitry 848 is coupled to a fourth portion of the control inputs of the PI circuitry 560 (CLK_CNTRL[96:127]).

The resistor 852 has a first terminal and a second terminal. The first terminal of the resistor 852 is coupled to a supply terminal, which provides a supply voltage (e.g., V_{DD}, AVDD, etc.). The second terminal of the resistor 852 is coupled to the capacitor 860, the resistor 868 and the transistor 880.

The resistor 856 has a first terminal and a second terminal. The first terminal of the resistor 856 is coupled to the supply terminal, which provides the supply voltage. The second terminal of the resistor 856 is coupled to the capacitor 860, the transistor 872, and the resistor 876.

The capacitor 860 has a first terminal, a second terminal, and a trim input. The first terminal of the capacitor 860 is coupled to the resistors 852, 868 and the transistor 880. The second terminal of the capacitor 860 is coupled to the resistors 856, 876 and the transistor 872. The trim input of the capacitor 860 is coupled to the trim register 864. The trim register 864 provides a first capacitor trim code (C1_CODE). The first capacitor trim code controls the capacitance of the capacitor 860. In some examples, the trim register 864 is a register or a portion of memory.

The resistor 868 has a first terminal and a second terminal. The first terminal of the resistor 868 is coupled to the resistor 852, the capacitor 860, and the transistor 880. The second terminal of the resistor 868 is coupled to the transistor 872 and the first output of the PI circuitry 560 (PI_CLK).

The transistor 872 has a first terminal, a second terminal, and a control terminal. The first terminal of the transistor 872 is coupled to the resistor 868 and the PI clock output of the PI circuitry 560 (PI_CLK). The second terminal of the transistor 872 is coupled to the transistors 804, 816, 828, 840 and the capacitor 884. The control terminal of the transistor 872 is coupled to the resistors 856, 876 and the capacitor 860.

The resistor 876 has a first terminal and a second terminal. The first terminal of the resistor 876 is coupled to the resistor 856, the capacitor 860, and the transistor 872. The second terminal of the resistor 876 is coupled to the transistor 880 and the inverted PI clock output of the PI circuitry 560 (PI_CLKZ).

The transistor 880 has a first terminal, a second terminal, and a control terminal. The first terminal of the transistor 880 is coupled to the resistor 876 and the inverted PI clock output of the PI circuitry 560 (PI_CLKZ). The second terminal of the transistor 880 is coupled to the transistors 808, 820, 832, 844 and the capacitor 884. The control terminal of the transistor 880 is coupled to the resistors 852, 868 and the capacitor 860.

The capacitor 884 has a first terminal, a second terminal, and a trim input. The first terminal of the capacitor 884 is coupled to the transistors 804, 816, 828, 840, 872. The second terminal of the capacitor 884 is coupled to the transistors 808, 820, 832, 844, 880. The trim input of the capacitor 884 is coupled to the trim register 888. The trim register 888 provides a second capacitor trim code (C2_CODE). The second capacitor trim code controls the capacitance of the capacitor 884. In some examples, the trim register 888 is a register or a portion of memory.

In the example of FIG. 8, the transistors 804, 808, 816, 820, 828, 832, 840, 844, 872, 880 are n-channel metal-oxide semiconductor field-effect transistors (MOSFETs). Alternatively, the transistors 804, 808, 816, 820, 828, 832, 840, 844, 872, 880 may be n-channel field-effect transistors (FETs), n-channel insulated-gate bipolar transistors (IGBTs), n-channel junction field effect transistors (JFETs), NPN bipolar junction transistors (BJTs) or, with slight modifications, p-type equivalent devices. The transistors 804, 808, 816, 820, 828, 832, 840, 844, 872, 880 may be depletion mode devices, drain-extended devices, enhancement mode devices, natural transistors or other type of device structure transistors. Furthermore, the transistors 804, 808, 816, 820, 828, 832, 840, 844, 872, 880 may be implemented in/over a silicon substrate (Si), a silicon carbide substrate (SiC), a gallium nitride substrate (GaN) or a gallium arsenide substrate (GaAs).

FIG. 9 is a timing diagram 900 of example clock signals from the clock circuitry 570 of FIG. 5. In the example of FIG. 9, the timing diagram 900 includes an in-phase clock signal 910 (I_CLK), a quadrature clock signal 920 (Q_CLK), an inverted in-phase clock signal 930, and an inverted quadrature clock signal 940 (Q_CLKZ).

The in-phase clock signal 910 is a sinusoidal signal having a zero-degree phase shift. The clock circuitry 570 provides the in-phase clock signal 910 at the first clock input of the PI circuitry 560 of FIG. 5 (I_CLK). The quadrature clock signal 920 is a sinusoidal signal having a ninety-degree phase shift in comparison to the in-phase clock signal 910. The clock circuitry 570 provides the quadrature clock signal 920 at the second clock input of the PI circuitry 560 (Q_CLK).

The inverted in-phase clock signal 930 is a sinusoidal signal having a one-hundred-and-eighty-degree phase shift in comparison to the in-phase clock signal 910. The clock circuitry 570 provides the inverted in-phase clock signal 930 at the first inverted clock input of the PI circuitry 560 (I_CLKZ). In some examples, the clock circuitry 570 produces the inverted in-phase clock signal 930 responsive to inverting the in-phase clock signal 910. For example, at a first time 950, the in-phase clock signal 910 has a falling edge and the inverted in-phase clock signal 930 has a rising edge.

The inverted quadrature clock signal 940 is a sinusoidal signal having a fifty percent duty cycle and a two-hundred-and-seventy-degree phase shift in comparison to the in-phase clock signal 910. The clock circuitry 570 provides the inverted quadrature clock signal 940 at the second inverted clock input of the PI circuitry 560 (Q_CLKZ). In some examples, the clock circuitry 570 produces the inverted quadrature clock signal 940 responsive to inverting the quadrature clock signal 920. For example, at a second time 960, the quadrature clock signal 920 has a falling edge and the inverted quadrature clock signal 940 has a rising edge.

Also, the in-phase clock signal 910, the quadrature clock signal 920, the inverted in-phase clock signal 930, and the inverted quadrature clock signal 940 have the same frequency. In some examples, at the first time 950, the in-phase clock signal 910 has a falling edge and the inverted in-phase clock signal 930 has a rising edge and at the second time 960, the quadrature clock signal 920 has a falling edge and the inverted quadrature clock signal 940 has a rising edge. In such examples, at a third time 970, the in-phase clock signal 910 has a rising edge and the inverted in-phase clock signal 930 has a falling edge and at a fourth time 980, the quadrature clock signal 920 has a rising edge and the inverted quadrature clock signal 940 has a falling edge.

FIG. 10 is a timing diagram 1000 of example phase interpolator operations of the PI circuitry 560 of FIGS. 5, 7, and 8, or more generally of the retimer circuitry 500 of FIG. 5. In the example of FIG. 10, the timing diagram 1000 includes a serial data stream 1010 (SERIAL_DATA), a first CML PI clock signal 1020A, a first CMOS PI clock signal 1020B (PI_CLK_CMOS(CLK_CNTRL[0])), a second CML PI clock signal 1030A, a second CMOS PI clock signal 1030B (PI_CLK_CMOS(CLK_CNTRL[N/2])), a third CML PI clock signal 1040A, and a third CMOS PI clock signal 1040B (PI_CLK_CMOS(CLK_CNTRL[N])). The serial data stream 1010 represents the input of the retimer circuitry 500.

The first CMOS PI clock signal 1020B represents the output of the CML to CMOS converter circuitry 590 of FIG. 5 responsive to the PI circuitry 560 of FIG. 5 receiving a first clock control value (CLK_CNTRL[0]) from the clock control circuitry 550 of FIG. 5. In example operations, the PI circuitry 560 generates the CML PI clock signal 1020A having a phase corresponding to the first clock control value. In such example operations, the CML to CMOS converter circuitry 590 converts the alternating currents of the CML PI clock signal 1020A to logic levels of the first CMOS PI clock signal 1020B. Similarly, the second CMOS PI clock signal 1030B represents the output of the CML to CMOS converter circuitry 590 responsive to the CML PI clock signal 1030A from the PI circuitry 560. The PI circuitry 560 produces the CML PI clock signal 1030A responsive to receiving a second clock control value (CLK_CNTRL[N/2]) from the clock control circuitry 550. The third CMOS PI clock signal 1040B represents the output of the CML to CMOS converter circuitry 590 responsive to the CML PI clock signal 1040A from the PI circuitry 560. The PI circuitry 560 produces the CML PI clock signal 1040A responsive to receiving a third clock control value (CLK_CNTRL[N]) from the clock control circuitry 550. Advantageously, the PI circuitry 560 adjusts the phase of the CMOS PI clock signals 1020, 1030, 1040 responsive to different clock control values.

At a first time 1050, the serial data stream 1010 may be transitioning between logical states, such as a rising edge or a falling edge. Also at the first time 1050, the first CMOS clock signal 1020B has a rising edge corresponding to the first clock control value. In example operations, if the sampling circuitry 520 samples the serial data stream 1010 at the first time 1050, the phase detector circuitry 530 determines a less than fifty percent probability of the edge sample matching the data sample.

At a second time 1060, the serial data stream 1010 remains at a settled logical state, such as a logical one or a logical zero. Also at the second time 1060, the second CMOS clock signal 1030B has a rising edge corresponding to the second clock control value. In example operations, if the sampling circuitry 520 samples the serial data stream 1010 at the second time 1060, the phase detector circuitry 530 determines a fifty percent probability of the edge sample of the sampling circuitry 540 matching the data sample.

At a third time 1070, the serial data stream 1010 may be transitioning between logical states, such as a rising edge or a falling edge. Also at the third time 1070, the third CMOS clock signal 1040B has a rising edge corresponding to the third clock control value. In example operations, if the sampling circuitry 520 samples the serial data stream 1010 at the third time 1070, the phase detector circuitry 530 determines a greater than fifty percent probability of the edge sample matching the data sample. Advantageously, adjusting the clock control value changes the probability of the data sample of the sampling circuitry 520 matching the edge sample of the sampling circuitry 540.

FIG. 11 is a flowchart representative of example machine-readable instructions or example operations 1100 that may be at least one of executed, instantiated, or performed using an example implementation of the PI circuitry 560 of FIGS. 5, 7, and 8. The example operations 1100 of FIG. 11 begin at Block 1105, at which the PI circuitry 560 receives inverted and non-inverted in-phase (I) and quadrature (Q) clock signals. In example operations, the clock circuitry 570 of FIG. 5 produces the in-phase clock signal 910 (I_CLK) and the quadrature clock signal 920 (Q_CLK). In some examples, the clock circuitry 570 also produces the inverted in-phase clock signal 930 (I_CLKZ) and the inverted quadrature clock signal 940 (Q_CLKZ). Alternatively, the PI circuitry 560 may include invertor circuitry to produce the inverted in-phase clock signal 930 (I_CLKZ) and the inverted quadrature clock signal 940 (Q_CLKZ).

The PI circuitry 560 receives a PI clock control value. (Block 1110). In example operations, the clock control circuitry 550 of FIG. 5 supplies a clock control value (CLK_CNTRL[0:N]). In such example operations, the clock control value corresponds to a phase of the PI clock output of the PI circuitry 560. In some examples, as illustrated in FIGS. 7 and 8, different portions of the clock control value control one of the V-I circuitry 720, 730, 740, 750.

The V-I circuitry 720 sinks a first current based on the non-inverted in-phase clock and a first portion of the PI clock control value. (Block 1115). In example operations, the V-I circuitry 720 receives a first portion of the clock control value at the control input of the PI circuitry 560. For example, the V-I circuitry 720 receives the first thirty-two bits of the clock control value (CLK_CNTRL[0:31]). In such example operations, the first portion of the clock control value sets the magnitude of the current source circuitry 812 of FIG. 8. Also, the transistor 804 of FIG. 8 sinks a first current from the filter circuitry 770 of FIG. 7 responsive to the in-phase clock signal (I_CLK) having the magnitude of the current source circuitry 812.

The V-I circuitry 720 sinks a second current based on the inverted in-phase clock and the first portion of the PI clock control value. (Block 1120). In example operations, the current source circuitry 812 sinks a current responsive to the first portion of the clock control value. In such example operations, the transistor 808 of FIG. 8 sinks a second current from the filter circuitry 770 responsive to the inverted in-phase clock signal (I_CLKZ) having a magnitude set by the current source circuitry 812.

The V-I circuitry 730 sinks a third current based on the inverted in-phase clock and a second portion of the PI clock control value. (Block 1125). In example operations, the V-I circuitry 730 receives a second portion of the clock control value at the control input of the PI circuitry 560. For example, the V-I circuitry 730 receives the second thirty-two bits of the clock control value (CLK_CNTRL[32:63]). In such example operations, the second portion of the clock control value sets the magnitude of the current source circuitry 824 of FIG. 8. Also, the transistor 816 of FIG. 8 sinks a third current from the filter circuitry 770 responsive to the inverted in-phase clock signal (I_CLKZ) having the magnitude of the current source circuitry 824.

The V-I circuitry 730 sinks a fourth current based on the non-inverted in-phase clock and the second portion of the PI clock control value. (Block 1130). In example operations, the current source circuitry 824 sinks a current responsive to the second portion of the clock control value. In such example operations, the transistor 820 of FIG. 8 sinks a fourth current from the filter circuitry 770 responsive to the in-phase clock signal (I_CLK) having a magnitude set by the current source circuitry 824.

The V-I circuitry 740 sinks a fifth current based on the non-inverted quadrature clock and a third portion of the PI clock control value. (Block 1135). In example operations, the V-I circuitry 740 receives a third portion of the clock control value at the control input of the PI circuitry 560. For example, the V-I circuitry 740 receives the third thirty-two bits of the clock control value (CLK_CNTRL[64:95]). In such example operations, the third portion of the clock control value sets the magnitude of the current source circuitry 836 of FIG. 8. Also, the transistor 828 of FIG. 8 sinks a fifth current from the filter circuitry 770 responsive to the quadrature clock signal (Q_CLK) having the magnitude of the current source circuitry 836.

The V-I circuitry 740 sinks a sixth current based on the inverted quadrature clock and the third portion of the PI clock control value. (Block 1140). In example operations, the current source circuitry 836 sinks a current responsive to the third portion of the clock control value. In such example operations, the transistor 832 of FIG. 8 sinks a sixth current from the filter circuitry 770 responsive to the inverted quadrature clock signal (Q_CLKZ) having a magnitude set by the current source circuitry 836.

The V-I circuitry 750 sinks a seventh current based on the inverted quadrature clock and a fourth portion of the PI clock control value. (Block 1145). In example operations, the V-I circuitry 750 receives a fifth portion of the clock control value at the control input of the PI circuitry 560. For example, the V-I circuitry 750 receives the fourth thirty-two bits of the clock control value (CLK_CNTRL[96:127]). In such example operations, the fourth portion of the clock control value sets the magnitude of the current source circuitry 848 of FIG. 8. Also, the transistor 840 of FIG. 8 sinks a seventh current from the filter circuitry 770 responsive to the inverted quadrature clock signal (Q_CLKZ) having the magnitude of the current source circuitry 848.

The V-I circuitry 750 sinks an eighth current based on the non-inverted quadrature clock and the fourth portion of the PI clock control value. (Block 1150). In example operations, the current source circuitry 848 sinks a current responsive to the fourth portion of the clock control value. In such example operations, the transistor 844 of FIG. 8 sinks an eighth current from the filter circuitry 770 responsive to the quadrature clock signal (Q_CLK) having a magnitude set by the current source circuitry 848.

The filter circuitry 770 combines the first, third, fifth, and seventh currents at a first node (N1). (Block 1155). In example operations, the transistors 804, 816, 828, 840 sink current from the transistor 872 of FIG. 8 and the capacitor 884 of FIG. 8. In some examples, the combination of the currents of the transistors 804, 816, 828, 840 at the transistor 872 is referred to as mixing or mixing currents.

The filter circuitry 770 combines the second, fourth, sixth, and eighth currents at a second node (N2). (Block 1160). In example operations, the transistors 808, 820, 832, 844 sink current from the transistor 880 of FIG. 8 and the capacitor 884. In some examples, the combination of the currents of the transistors 808, 820, 832, 844 at the transistor 880 is referred to as mixing or mixing currents.

The load circuitry 760 compensates for the load at the first and second nodes (N1, N2). (Block 1165). In example operations, the resistances of the resistors 852, 856 of FIG. 8 compensates for the transconductance of the transistors 872, 880. Such compensation produces a virtual ground (also referred to as a virtual common potential) at the source terminals of the transistors 872, 880. A virtual ground allows the currents of the V-I circuitry 720, 730, 740, 750 to mix without changing the load at the PI clock output of the PI circuitry 560 (PI_CLK). Advantageously, compensating the transconductance of the transistors 872, 880 with the resistors 852, 856 improves linearity by setting a load at outputs of the PI circuitry 560 that is independent of currents from the V-I circuitry 720, 730, 740, 750.

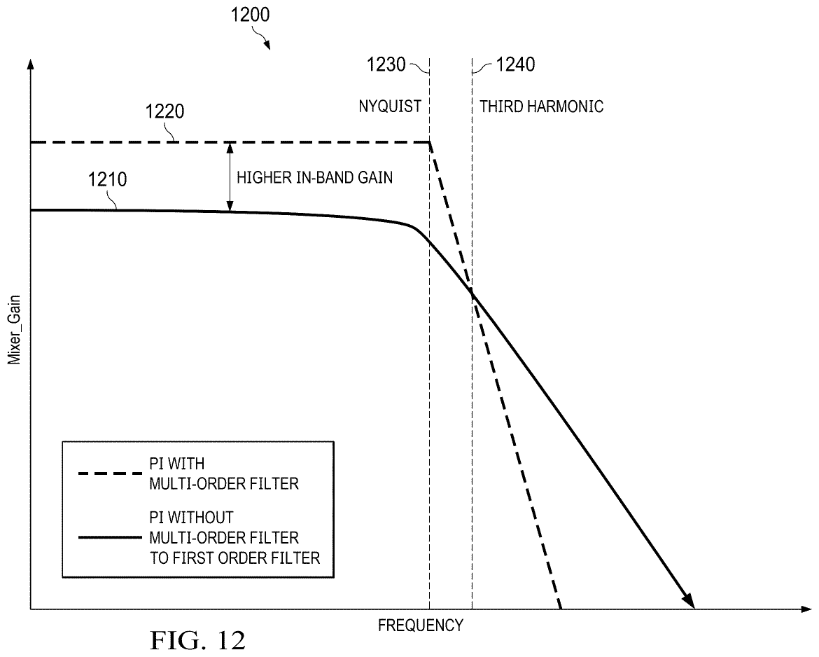

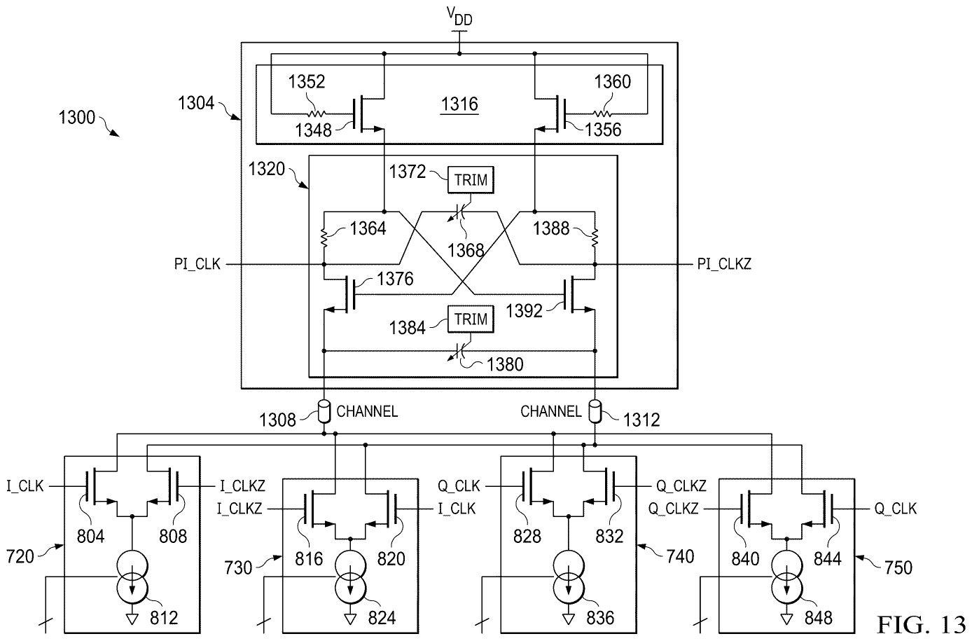

The filter circuitry 770 filters the combined currents at the first and second nodes (N1, N2). (Block 1170). In example operations, the conduction of current by the transistor 880 regulates the conduction of current by the transistor 872. Similarly, the conduction of the current by the transistor 872 regulates the conduction of current by the transistor 880. Such a cross coupled structure between the transistors 872, 880 forms positive feedback path. In some examples, the structure of the transistors 872, 880 may be referred to as a cross coupled pair. In such example operations, the capacitors 860, 884 limit the response time of the positive feedback paths responsive to changes in voltages of the filter circuitry 770. In some examples, the trim registers 864, 888 set the capacitance of the capacitors 860, 884 to regulate the frequency response of the filter circuitry 770. For example, increasing the capacitance of the capacitors 860, 884 increases the falloff of the frequency response of the filter circuitry 770. Such an example is further illustrated and described in connection with FIG. 12. Advantageously, the filter circuitry 770 forms a second order filter, which converts the CMOS logic of the in-phase and quadrature clock signals to CML.

The filter circuitry 770 amplifies the filtered current from the first and second nodes (N1, N2) at third and fourth nodes (N3, N4). (Block 1175). In example operations, the transistors 872, 880 set the PI clock output of the PI circuitry 560 responsive to sinking the mixed currents through the resistors 868, 876 of FIG. 8. In such example operations, the resistors 868, 876 produce a voltage difference in relation to the supply voltage responsive to the conduction of current by the transistors 872, 880. Advantageously, the resistors 868, 876 increase the potential voltage swing (e.g., magnitude) of the PI clock output of the PI circuitry 560. Advantageously, the resistors 868, 876 increase the gain of the PI circuitry 560.

The PI circuitry 560 supplies inverting and non-inverting interpolated clock signals at the third and fourth nodes. (Block 1180). In example operations, the PI clock output of the PI circuitry 560 (PI_CLK) provides a CML PI clock signal. In such example operations, the inverted PI clock output of the PI circuitry 560 (PI_CLKZ) provides an inverted CML PI clock signal. Advantageously, the CML PI clock signals have less second order harmonic noise in comparison to a CMOS PI clock signal.

Example methods are described with reference to the flowchart illustrated in FIG. 11. However, many other methods of implementing the PI circuitry 560 of FIGS. 5, 7, and 8 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 12 is a plot 1200 of example filter operations of the PI circuitry 560 of FIGS. 5, 7, and 8. In the example of FIG. 12, the plot 1200 illustrates a first order PI frequency response 1210 and a multi-order filtered PI frequency response 1220. The first order PI frequency response 1210 illustrates example filtering operations of PI circuitry without the multi-order filter circuitry 710 of FIGS. 7 and 8. The multi-order filtered PI frequency response 1220 illustrates example filtering operations of the PI circuitry 560 with the multi-order filter circuitry 710.

In the example of FIG. 12, prior to the Nyquist frequency 1230, the multi-order filtered PI frequency response 1220 has a higher gain in comparison to the first order PI frequency response 1210. Advantageously, the resistors 868, 876 and the cross-coupled structure of the transistors 872, 880 support higher gains by driving the PI clock outputs of the PI circuitry 560 using currents from the supply terminal (V_{DD}). Advantageously, the filter circuitry 770 supports higher gains in the pass band frequencies in comparison to the gain of the non-filtered PI frequency response 1210.

In the example of FIG. 12, between the Nyquist frequency 1230 and a third harmonic frequency 1240, the multi-order filtered PI frequency response 1220 has a steeper magnitude drop-off in comparison to the first order PI frequency response 1210. Advantageously, the capacitors 860, 884 increase the rejection of frequencies beyond the third harmonic frequency 1240. Advantageously, adjusting the first and second capacitor trim codes (C1_CODE, C2_CODE) of the trim registers 864, 888 modifies the rate of magnitude drop-off of the multi-order filtered PI frequency response 1220.

FIG. 13 is a schematic diagram of example PI circuitry 1300, which is another example of the PI circuitry 560 of FIGS. 5, 7, and 8 for oscillator multiplexing. In the example of FIG. 13, the PI circuitry 1300 includes the V-I circuitry 720, 730, 740, 750 of FIG. 7, multi-order filter circuitry 1304, a first channel 1308, and a second channel 1312. The example multi-order filter circuitry 1304 of FIG. 13 includes example load circuitry 1316 and example filter circuitry 1320. The example load circuitry 1316 of FIG. 13 includes a first example transistor 1348, a first example resistor 1352, a second example transistor 1356, and a second example resistor 1360. The example filter circuitry 1320 of FIG. 13 includes a first example resistor 1364, a first example capacitor 1368, a first example trim register 1372, a first example transistor 1376, a second example capacitor 1380, a second example trim register 1384, a second example resistor 1388, and a second example transistor 1392.

The PI circuitry 1300 has a first clock input, a first inverted clock input, a second clock input, a second inverted clock input, control inputs, a PI clock output, and an inverted PI clock output. The first clock input of the PI circuitry 1300 is structured to be coupled to the clock circuitry 570, which provides an in-phase clock signal (I_CLK). The first inverted clock input of the PI circuitry 1300 is structured to be coupled to the clock circuitry 570, which provides an inverted in-phase clock signal (I_CLKZ). The second clock input of the PI circuitry 1300 is structured to be coupled to the clock circuitry 570, which provides a quadrature clock signal (Q_CLK). The second inverted clock input of the PI circuitry 1300 is structured to be coupled to the clock circuitry 570, which provides an inverted quadrature clock signal (Q_CLKZ). Such in-phase and quadrature clock signals are referred to as IQ clock signals. Examples of the IQ clock signals are illustrated and described in connection with FIG. 9. The control inputs of the PI circuitry 1300 are structured to be coupled to the clock control circuitry 550, which provides clock control value (CLK_CNTRL[0:N]). The PI clock output of the PI circuitry 1300 is structured to be coupled to the CML to CMOS converter circuitry 590. The PI clock output provides a PI clock signal (PI_CLK). The inverted PI clock output of the PI circuitry 1300 provides an inverted PI clock signal (PI_CLKZ).

Alternatively, the clock inputs of the PI circuitry 1300 are coupled to one or more voltage-controlled oscillators using poly phase filter circuitry. In such examples, the PI circuitry 1300 controls the contributions of oscillator signals responsive to the clock control values. Advantageously, the control of the clock control values may structure the PI circuitry 1300 to multiplex VCO signals. Advantageously, the outputs of the V-I circuitry 720, 730, 740, 750 is a CML signal that is capable of traversing relatively large electrical traces in comparison to a corresponding CMOS signal.

The multi-order filter circuitry 1304 has a first input, a second input, a first output, and a second output. The first and second inputs of the multi-order filter circuitry 1304 are coupled to the channels 1308, 1312. The first output of the multi-order filter circuitry 1304 is coupled to the PI clock output of the PI circuitry 1300 (PI_CLK). The second output of the multi-order filter circuitry 1304 is coupled to the inverted PI clock output of the PI circuitry 1300 (PI_CLKZ).

The channel 1308 has a first terminal and a second terminal. The first terminal of the channel 1308 is coupled to the V-I circuitry 720, 730, 740, 750. The second terminal of the channel 1308 is coupled to the multi-order filter circuitry 1304. The channel 1312 has a first terminal and a second terminal. The first terminal of the channel 1312 is coupled to the V-I circuitry 720, 730, 740, 750. The second terminal of the channel 1312 is coupled to the multi-order filter circuitry 1304.

In some examples, the channels 1308, 1312 are electrical traces, which provide a conductive path for currents of the V-I circuitry 720, 730, 740, 750 to traverse. In such examples, the channels 1308, 1312 couple the V-I circuitry 720, 730, 740, 750 to the multi-order filter circuitry 1304 across a system on chip (SoC) package. In other examples, the channels 1308, 1312 are connectors, which provide an external conductive path for currents of the V-I circuitry 720, 730, 740,750. In such examples, the PI circuitry 1300 may be implements in a multi-chip module (MCM). For example, the V-I circuitry 720, 730, 740, 750 are implemented on one or more modules and the multi-order filter circuitry 1304 is implemented on another module.

The load circuitry 1316 has an input, a first output, and a second output. The input of the load circuitry 1316 is coupled to the supply terminal, which provides the supply voltage. The first and second outputs of the load circuitry 1316 are coupled to the filter circuitry 1320.

The filter circuitry 1320 has a first input, a second input, a third input, a fourth input, a first output, and a second output. The first input of the filter circuitry 1320 is coupled to the channel 1308. The second input of the filter circuitry 1320 is coupled to the channel 1312. The third and fourth inputs of the filter circuitry 1320 are coupled to the load circuitry 1316. The first output of the filter circuitry 1320 is coupled to the PI clock output of the PI circuitry 1300 (PI_CLK). The second output of the filter circuitry 1320 is coupled to the inverted PI clock output of the PI circuitry 1300 (PI_CLKZ).

The transistor 1348 has a first terminal, a second terminal, and a control terminal. The first terminal of the transistor 1348 is coupled to the supply terminal, which provides the supply voltage. The second terminal of the transistor 1348 is coupled to the resistor 1364 and the transistor 1392. The control terminal of the transistor 1348 is coupled to the resistor 1352.

The resistor 1352 has a first terminal and a second terminal. The first terminal of the resistor 1352 is coupled to the supply terminal, which provides the supply voltage. The second terminal of the resistor 1352 is coupled to the transistor 1348.

The transistor 1356 has a first terminal, a second terminal, and a control terminal. The first terminal of the transistor 1356 is coupled to the supply terminal, which provides the supply voltage. The second terminal of the transistor 1356 is coupled to the transistor 1376 and the resistor 1388. The control terminal of the transistor 1356 is coupled to the resistor 1360.

The resistor 1360 has a first terminal and a second terminal. The first terminal of the resistor 1360 is coupled to the supply terminal, which provides the supply voltage. The second terminal of the resistor 1360 is coupled to the transistor 1356.

The resistor 1364 has a first terminal and a second terminal. The first terminal of the resistor 1364 is coupled to the transistors 1348, 1392. The second terminal of the resistor 1364 is coupled to the capacitor 1368, the transistor 1376, and the PI clock output of the PI circuitry 1300 (PI_CLK).

The capacitor 1368 has a first terminal, a second terminal, and a trim input. The first terminal of the capacitor 1368 is coupled to the resistor 1364, the transistor 1376, and the PI clock output of the PI circuitry 1300 (PI_CLK). The second terminal of the capacitor 1368 is coupled to the resistor 1388, the transistor 1392, and the inverted PI clock output of the PI circuitry 1300 (PI_CLKZ). The trim input of the capacitor 1368 is coupled to the trim register 1372. The trim register 1372 provides a first capacitor trim code (C1_CODE). The first capacitor trim code controls the capacitance of the capacitor 1368. In some examples, the trim register 1372 is a register or a portion of memory.

The transistor 1376 has a first terminal, a second terminal, and a control terminal. The first terminal of the transistor 1376 is coupled to the resistor 1364, the capacitor 1368, and the PI clock output of the PI circuitry 1300 (PI_CLK). The second terminal of the transistor 1376 is coupled to the channel 1308 and the capacitor 1380. The control terminal of the transistor 1376 is coupled to the transistor 1356 and the resistor 1388.

The capacitor 1380 has a first terminal, a second terminal, and a trim input. The first terminal of the capacitor 1380 is coupled to the channel 1308 and the transistor 1376. The second terminal of the capacitor 1380 is coupled to the channel 1312 and the transistor 1392. The trim input of the capacitor 1380 is coupled to the trim register 1384. The trim register 1384 provides a second capacitor trim code (C2_CODE). The second capacitor trim code controls the capacitance of the capacitor 1380. In some examples, the trim register 1384 is a register or a portion of memory.

The resistor 1388 has a first terminal and a second terminal. The first terminal of the resistor 1388 is coupled to transistors 1356, 1376. The second terminal of the resistor 1388 is coupled to the capacitor 1368, the transistor 1392, and the inverted PI clock output of the PI circuitry 1300.

The transistor 1392 has a first terminal, a second terminal, and a control terminal. The first terminal of the transistor 1392 is coupled to the capacitor 1368, the resistor 1388, and the inverted clock output of the PI circuitry 1300 (PI_CLKZ). The second terminal of the transistor 1392 is coupled to the channel 1312 and the capacitor 1380. The control terminal of the transistor 1392 is coupled to the transistor 1348 and the resistor 1364.

In the example of FIG. 13, the transistors 1348, 1356, 1376, 1392 are n-channel MOSFETs. Alternatively, the transistors 1348, 1356, 1376, 1392 may be n-channel FETs, n-channel IGBTs, n-channel JFETs, NPN BJTs, or, with slight modifications, p-type equivalent devices. The transistors 1348, 1356, 1376, 1392 may be depletion mode devices, drain-extended devices, enhancement mode devices, natural transistors or other type of device structure transistors. Furthermore, the transistors 1348, 1356, 1376, 1392 may be implemented in/over a silicon substrate (Si), a silicon carbide substrate (SiC), a gallium nitride substrate (GaN) or a gallium arsenide substrate (GaAs).

In example operations, the transistors 1348, 1356 and the resistors 1352, 1360 improve matching the load of the transistors 1376, 1392 at the outputs of the PI circuitry 1300. Such impedance matching increases the stability of the virtual ground between the multi-order filter circuitry 1304 and the channels 1308, 1312. In such example operations, improving the impedance matching of the transistors 1376, 1392 accounts for additional impedances of the channels 1308, 1312. Such channels 1308, 1312 add additional parasitic impedances at the inputs of the filter circuitry 1320. Advantageously, the virtual ground formed by the impedance matching of the load circuitry 1316 to the filter circuitry 1320 supports the additional parasitics of extended traces. Advantageously, improving impedance matching to support the channels 1308, 1312 allows systems to position the V-I circuitry 720, 730, 740, 750 in proximity to clock or oscillator signal sources. Advantageously, positioning the V-I circuitry 720, 730, 740, 750 in proximity to signal sources reduce power, area, complexity, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means +/−10 percent of the stated value, or, if the value is zero, a reasonable range of values around zero.

Modifications are possible in the described embodiments, and other embodiments are possible, within the scope of the claims.

What is claimed is:

1. An apparatus comprising:
first voltage-to-current (V-I) circuitry having a first terminal and a second terminal;
second V-I circuitry having a first terminal and a second terminal;
a first transistor having a first terminal, a second terminal, and a control terminal, the first terminal of the first transistor coupled to the first terminal of the first V-I circuitry and the first terminal of the second V-I circuitry;
a second transistor having a first terminal, a second terminal, and a control terminal, the first terminal of the second transistor coupled to the second terminal of the first V-I circuitry and the second terminal of the second V-I circuitry;
a first resistor having a first terminal and a second terminal, the first terminal of the first resistor coupled to the second terminal of the first transistor, the second terminal of the first resistor coupled to the control terminal of the second transistor; and
a second resistor having a first terminal and a second terminal, the first terminal of the second resistor coupled to the second terminal of the second transistor, the second terminal of the second resistor coupled to the control terminal of the first transistor.

2. The apparatus of claim 1, wherein the first V-I circuitry includes:
a third transistor having a first terminal and a second terminal, the first terminal of the third transistor coupled to the first terminal of the second V-I circuitry and the first terminal of the first transistor;
a fourth transistor having a first terminal and a second terminal, the first terminal of the fourth transistor coupled to the second terminal of the second V-I circuitry and the first terminal of the second transistor; and
current source circuitry having a terminal coupled to the second terminal of the third transistor and the second terminal of the fourth transistor.

3. The apparatus of claim 1, further comprising:
a third resistor having a first terminal and a second terminal, the first terminal of the third resistor coupled to the control terminal of the second transistor and the second terminal of the first resistor; and
a fourth resistor having a first terminal and a second terminal, the first terminal of the fourth resistor coupled to the control terminal of the first transistor and the second terminal of the second resistor, the second terminal of the fourth resistor coupled to the second terminal of the third resistor.

4. The apparatus of claim 1, further comprising a capacitor having a first terminal and a second terminal, the first terminal of the capacitor coupled to the first terminal of the first V-I circuitry, the first terminal of the second V-I circuitry, and the first terminal of the first transistor, the second terminal of the capacitor coupled to the second terminal of the first V-I circuitry, the second terminal of the second V-I circuitry, and the first terminal of the second transistor.

5. The apparatus of claim 4, wherein the capacitor is a first capacitor, and the apparatus further comprising a second capacitor having a first terminal and a second terminal, the first terminal of the second capacitor coupled to the second terminal of the first transistor and the first terminal of the first resistor, the second terminal of the second capacitor coupled to the second terminal of the second transistor and the first terminal of the second resistor.

6. The apparatus of claim 4, wherein the capacitor is a first capacitor, and the apparatus further comprising a second capacitor having a first terminal and a second terminal, the first terminal of the second capacitor coupled to the control terminal of the second transistor and the second terminal of the first resistor, the second terminal of the second capacitor is coupled to the control terminal of the first transistor and the second terminal of the second resistor.

7. The apparatus of claim 1, further comprising:
a third transistor having a first terminal, a second terminal, and a control terminal, the first terminal of the third transistor coupled to the control terminal of the second transistor and the second terminal of the first resistor;
a third resistor having a first terminal and a second terminal, the first terminal of the third resistor coupled to the control terminal of the third transistor;
a fourth transistor having a first terminal, a second terminal, and a control terminal, the first terminal of the fourth transistor coupled to the control terminal of the first transistor and the second terminal of the second resistor; and
a fourth resistor having a first terminal and a second terminal, the first terminal of the fourth resistor coupled to the control terminal of the fourth transistor, the second terminal of the fourth resistor coupled to the second terminal of the third transistor, the second terminal of the third resistor, and the second terminal of the fourth transistor.

8. The apparatus of claim 1, wherein the first V-I circuitry further has a first input and a second input, the second V-I circuitry further has a first input and a second input, and the apparatus further comprising:
clock circuitry having a first clock output, a second clock output, a first inverted clock output, and a second inverted clock output, the first clock output of the clock circuitry coupled to the first input of the first V-I circuitry and the second input of the second V-I circuitry, the first inverted clock output of the clock circuitry coupled to the second input of the first V-I circuitry and the first input of the second V-I circuitry;
third V-I circuitry having a first input, a second input, a first terminal, and a second terminal; and
fourth V-I circuitry having a first input, a second input, a first terminal and a second terminal, the first input of the fourth V-I circuitry coupled to the second input of the third V-I circuitry and the second inverted clock output of the clock circuitry, the second input of the fourth V-I circuitry coupled to the first input of the third V-I circuitry and the second clock output of the clock circuitry.

9. The apparatus of claim 1, wherein the first V-I circuitry has a control input, the second V-I circuitry has a control input, and the apparatus further comprising:
phase detector circuitry having an input and an output;
clock control circuitry having an input, a first output, and a second output, the input of the clock control circuitry coupled to the output of the phase detector circuitry, the first output of the clock control circuitry coupled to the control input of the first V-I circuitry, the second output of the clock control circuitry coupled to the control input of the second V-I circuitry;
current mode logic (CML) to complementary metal oxide semiconductor (CMOS) converter circuitry having an input and an output, the input of the CML to CMOS converter circuitry coupled to the second terminal of the first transistor and the first terminal of the first resistor; and
sampling circuitry having a clock input and an output, the clock input of the sampling circuitry coupled to the output of the CML to CMOS converter circuitry, the output of the sampling circuitry coupled to the input of the phase detector circuitry.

10. An apparatus comprising:
clock circuitry having a first output and a second output;
phase interpolator circuitry including:
first voltage-to-current (V-I) circuitry having a first input, a second input, a first output, and a second output;
second V-I circuitry having a first input, a second input, a first output, and a second output, the first input of the second V-I circuitry coupled to the first output of the clock circuitry and the second input of the first V-I circuitry, the second input of the second V-I circuitry coupled to the second output of the clock circuitry and the first input of the first V-I circuitry; and
filter circuitry having a first input, a second input, and an output, the first input of the filter circuitry coupled to the first output of the first V-I circuitry and the first output of the second V-I circuitry, the second input of the filter circuitry coupled to the second output of the first V-I circuitry and the second output of the second V-I circuitry; and
current mode logic (CML) to complementary metal oxide semiconductor (CMOS) converter circuitry having an input coupled to the output of the filter circuitry.

11. The apparatus of claim 10, wherein the first V-I circuitry includes:
a first transistor having a first terminal, a second terminal, and a control terminal, the first terminal of the first transistor coupled to the first output of the second V-I circuitry and the first input of the filter circuitry, the control terminal of the first transistor coupled to the first output of the clock circuitry;
a second transistor having a first terminal, a second terminal, and a control terminal, the first terminal of the second transistor coupled to the second output of the second V-I circuitry and the second input of the filter circuitry, the control terminal of the first V-I circuitry coupled to the second output of the clock circuitry; and
current source circuitry having a terminal coupled to the second terminal of the first transistor and the second terminal of the second transistor.

12. The apparatus of claim 10, wherein the filter circuitry further has a third input and a fourth input, and the apparatus further comprising:
a first resistor having a first terminal and a second terminal, the first terminal of the first resistor coupled to the third input of the filter circuitry; and
a second resistor having a first terminal and a second terminal, the first terminal of the second resistor coupled to the fourth input of the filter circuitry, the second terminal of the second resistor coupled to the second terminal of the first resistor.

13. The apparatus of claim 10, wherein the filter circuitry includes:
a first transistor having a first terminal, a second terminal, and a control terminal, the first terminal of the first transistor coupled to the first output of the first V-I circuitry and the first output of the second V-I circuitry;
a first resistor having a first terminal and a second terminal, the first terminal of the first resistor coupled to the input of the CML to CMOS converter circuitry and the second terminal of the first transistor;
a second transistor having a first terminal, a second terminal, and a control terminal, the first terminal of the second transistor coupled to the second output of the first V-I circuitry and the second output of the second V-I circuitry, the control terminal of the second transistor coupled to the second terminal of the first resistor; and
a second resistor having a first terminal and a second terminal, the first terminal of the second resistor coupled to the second terminal of the second transistor, the second terminal of the second resistor coupled to the control terminal of the first transistor.

14. The apparatus of claim 13, further comprising:
a first capacitor having a first terminal and a second terminal, the first terminal of the first capacitor coupled to the second terminal of the first resistor and the control terminal of the second transistor, the second terminal of the first capacitor coupled to the control terminal of the first transistor and the second terminal of the second resistor; and
a second capacitor having a first terminal and a second terminal, the first terminal of the first capacitor coupled to the first output of the first V-I circuitry, the first output of the second V-I circuitry, and the first terminal of the first transistor, the second terminal of the second capacitor coupled to the second output of the first V-I circuitry, the second output of the second V-I circuitry, and the first terminal of the second transistor.

15. The apparatus of claim 13, further comprising:
a first capacitor having a first terminal and a second terminal, the first terminal of the first capacitor coupled to the input of the CML to CMOS converter circuitry, the second terminal of the first transistor, and the first terminal of the first resistor, the second terminal of the first capacitor coupled to the second terminal of the second transistor and the first terminal of the second resistor; and
a second capacitor having a first terminal and a second terminal, the first terminal of the first capacitor coupled to the first output of the first V-I circuitry, the first output of the second V-I circuitry, and the first terminal of the first transistor, the second terminal of the second capacitor coupled to the second output of the first V-I circuitry, the second output of the second V-I circuitry, and the first terminal of the second transistor.

16. The apparatus of claim 10, wherein the clock circuitry further has a third output and a fourth output, and the apparatus further comprising:
third V-I circuitry having a first input, a second input, a first output, and a second output; and
fourth V-I circuitry having a first input, a second input, a first output, and a second output, the first input of the fourth V-I circuitry coupled to the third output of the clock circuitry and the second input of the third V-I circuitry, the second input of the fourth V-I circuitry coupled to the fourth output of the clock circuitry and the first input of the third V-I circuitry, the first output of the fourth V-I circuitry coupled to the first output of the first V-I circuitry, the first output of the second V-I circuitry, the first input of the filter circuitry, and the first output of the third V-I circuitry, the second output of the fourth V-I circuitry coupled to the second output of the first V-I circuitry, the second output of the second V-I circuitry, the second input of the filter circuitry, and the second output of the third V-I circuitry.

17. An apparatus comprising:
first voltage-to-current (V-I) circuitry having a first output and a second output;
second V-I circuitry having a first output and a second output; and
filter circuitry having a first input and a second input, the first input of the filter circuitry coupled to the first output of the first V-I circuitry and the first output of the second V-I circuitry, the second input of the filter circuitry coupled to the second output of the first V-I circuitry and the second output of the second V-I circuitry, the filter circuitry configured to:
combine first currents at the first output of the first V-I circuitry and the first output of the second V-I circuitry;
combine second currents at the second output of the first V-I circuitry and the second output of the second V-I circuitry;
filter the combined first currents and the combined second currents; and
generate a current mode logic (CML) clock signal based on the filtering.

18. The apparatus of claim 17, wherein the filter circuitry further has a third input and a fourth input, and the apparatus further comprising load circuitry having a first output and a second output, the first output of the load circuitry coupled to the third input of the filter circuitry, the second output of the load circuitry coupled to the fourth input of the filter circuitry, the load circuitry configured to set the first and second inputs of the filter circuitry to a virtual common potential.

19. The apparatus of claim 17, wherein the filter circuitry further has an output, and the apparatus further comprising current mode logic (CML) to complementary metal oxide semiconductor (CMOS) converter circuitry having an input coupled to the output of the filter circuitry, the CML to CMOS converter circuitry configured to convert the CML clock signal to a CMOS clock signal.

20. The apparatus of claim 19, wherein the CML to CMOS converter circuitry further has an output, and the apparatus further comprising:
receiver circuitry having an output; and
sampling circuitry having a data input and a clock input, the data input of the sampling circuitry coupled to the output of the receiver circuitry, the clock input of the sampling circuitry coupled to the output of the CML to CMOS converter circuitry, the sampling circuitry configured to sample the data input based on the CMOS clock signal.
